(19) United States
(12) Patent Application Publication
(10) Pub. No.: US 2008/0217648 A1
(43) Pub. Date: Sep. 11, 2008

(54) LIGHT-EMITTING ELEMENT AND LIGHT-EMITTING DEVICE

(75) Inventor: Hiroki OHARA, Sagamihara (JP)

Correspondence Address: NIXON PEABODY, LLP, 401 9TH STREET, NW, SUITE 900, WASHINGTON, DC, 20004-2128, US

(73) Assignee: SEMICONDUCTOR ENERGY LABORATORY CO., LTD., Atsugi-shi (JP)

(21) Appl. No.: 12/041,796

(22) Filed: Mar. 4, 2008

(30) Foreign Application Priority Data
Mar. 7, 2007 (JP) 2007-056546

(51) Int. Cl. H01L 33/00

(52) U.S. Cl. 257/103; 257/E33.063

(57) ABSTRACT

An object is to provide a light-emitting element and a light-emitting device each of which consumes less power and has high emission efficiency, high performance, and high reliability. A light-emitting element has an EL layer provided with a light-emitting layer, which includes an inorganic light-emitting material containing a mixed-valence compound, between a pair of electrode layers. When an element in a given compound has a plurality of valences, this element is in a state that is referred to as a mixed-valence state and this compound is referred to as a mixed-valence compound. The mixed-valence compound affects charge mobility and emission color, and a light-emitting device having such a light-emitting element consumes less power, has high reliability and high image quality, and emits various colors of light.

### TECHNICAL FIELD

The present invention relates to a light-emitting element and a light-emitting device.

### BACKGROUND ART

In recent years, the development of liquid crystal display devices and electroluminescent display devices with thin film transistors (hereinafter also referred to as “TFTs”) integrated over a glass substrate has been progressing. Each of these display devices functions as a display device where thin film transistors are formed over a glass substrate using a thin film formation technique, and display elements such as liquid crystal elements or light-emitting elements (electroluminescent (hereinafter also referred to as EL) elements) are formed over various circuits including the thin film transistors.

Light-emitting elements using electroluminescence are distinguished by whether a light-emitting material is an organic compound or an inorganic compound. In general, the former is referred to as organic EL elements and the latter is referred to as inorganic EL elements.

Such light-emitting elements have many material-dependent problems in improving element characteristics. In order to overcome them, improvement in element structure, material development, and the like have been performed.

In order to improve element characteristics such as emission efficiency, there have been researches on element structure of inorganic EL elements in which nano-sized fine-particle powder is used for a light-emitting layer, an insulating layer, or the like provided in an EL element (for example, see Reference 1: Japanese Published Patent Application No. 2004-259546).

However, for such light-emitting elements as mentioned above, lowering of a drive voltage and precise adjustment of chromaticity of emission color for obtaining various emission colors are needed and further improvement is desired.

### DISCLOSURE OF INVENTION

In view of such problems, it is an object of the present invention to lower the drive voltage of a light-emitting element and to obtain various emission colors by precise adjustment of chromaticity. It is another object of the present invention to provide a light-emitting element and a light-emitting device each of which consumes less power and has high performance and high reliability.

According to one aspect of the present invention, a light-emitting element has an EL layer provided with a light-emitting layer, which includes an inorganic light-emitting material containing a mixed-valence compound, between a pair of electrode layers. In the present invention, a stacked layer of a light-emitting layer and an insulating layer between a pair of electrode layers is referred to as an EL layer. In addition, a light-emitting device can be manufactured by using the present invention.

Light-emitting elements using electroluminescence are distinguished by whether a light-emitting material is an organic compound or an inorganic compound. In general, the former is referred to as organic EL elements and the latter is referred to as inorganic EL elements. The light-emitting element of the present invention is an inorganic EL element using an inorganic light-emitting material as a light-emitting material.

Inorganic EL elements are classified into a dispersion-type inorganic EL element and a thin-film type inorganic EL element, depending on their element structures. The former and the latter are different in that the former has a light-emitting layer where particles of a light-emitting material are dispersed in a binder whereas the latter has a light-emitting layer formed of a thin film of a light-emitting material. However, the former and the latter have in common that electrons accelerated by a high electric field are necessary. It is to be noted that, as a mechanism of light emission to be obtained, there are donor-acceptor recombination type light emission that utilizes a donor level and an acceptor level, and localized type light emission that utilizes inner-shell electron transition of metal ions. In general, in many cases, a dispersion-type inorganic EL element generates donor-acceptor recombination type light emission, and a thin-film type inorganic EL element generates localized type light emission.

An inorganic light-emitting material that can be used in the present invention includes a base material and an impurity element which serves as a light-emission center. By changing impurity elements to be included, various colors of light emission can be performed. Plural kinds of impurity elements may be included. For example, in the case of donor-acceptor recombination type light emission, a light-emitting material that includes a first impurity element which forms a donor level and a second impurity element which forms an acceptor level as a light-emission center can be used. In the present invention, at least one of a base material and an activator, which are included in a light-emitting layer, contains a mixed-valence compound. It is needless to say that each of the base material and the activator, which are included in a light-emitting layer, may contain a mixed-valence compound.

In this specification, relative to a base material, an impurity element serving as a light-emission center is referred to as an activator, and another impurity element that is further added is referred to as a secondary activator. The first impurity element which forms a donor level is also referred to as a coactivator, and a light-emitting material containing the second impurity element which forms an acceptor level is also referred to as an activator.

Light-emitting devices to which the present invention can be applied include a light-emitting device in which a light-emitting element and a thin film transistor (hereinafter also referred to as a TFT) are connected to each other, and the like.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state is a compound of a transition metal or a rare earth metal which can have a plurality of valences. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound using the present invention can be formed using a material to be described in Embodiment Mode 1.

According to one aspect of the present invention, a light-emitting element includes a light-emitting layer, which includes an inorganic light-emitting material containing a mixed-valence compound, between a first electrode layer and a second electrode layer.

According to another aspect of the present invention, a light-emitting element includes a light-emitting layer which includes an inorganic light-emitting material containing a base material and an impurity element, between a first electrode layer and a second electrode layer. At least one of the base material and the impurity element is a mixed-valence compound.

According to another aspect of the present invention, a light-emitting element includes a light-emitting layer, which includes an inorganic light-emitting material containing a base material, a first impurity element, and a second impurity element, between a first electrode layer and a second electrode layer. At least one of the base material, the first impurity element and the second impurity element is a mixed-valence compound.

According to another aspect of the present invention, a light-emitting device includes a light-emitting element provided with a light-emitting layer, which includes an inorganic light-emitting material containing a mixed-valence compound, between a first electrode layer and a second electrode layer.

According to another aspect of the present invention, a light-emitting device includes a light-emitting element provided with a light-emitting layer, which includes an inorganic light-emitting material containing a base material and an impurity element, between a first electrode layer and a second electrode layer. At least one of the base material and the impurity element is a mixed-valence compound.

According to another aspect of the present invention, a light-emitting device includes a light-emitting element provided with a light-emitting layer, which includes an inorganic light-emitting material containing a base material, a first impurity element, and a second impurity element, between a first electrode layer and a second electrode layer. At least one of the base material, the first impurity element, and the second impurity element is a mixed-valence compound.

In each of the above aspects, the light-emitting element may further include an insulating layer on at least one of the first electrode layer side and the second electrode layer side of the light-emitting layer.

Because the light-emitting element of the present invention has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage and can achieve a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element using the present invention consumes less power, has high reliability and high image quality, and emits various colors of light.

### BRIEF DESCRIPTION OF DRAWINGS

FIG. 1 is a diagram illustrating a light-emitting element of the present invention.

FIGS. 2A to 2C are diagrams each illustrating a light-emitting element of the present invention.

FIGS. 3A to 3C are diagrams each illustrating a light-emitting element of the present invention.

FIGS. 4A and 4B are diagrams each illustrating a model of a light-emitting element of the present invention.

FIG. 5 is a diagram illustrating a model of a light-emitting element of the present invention.

FIG. 6 is a diagram illustrating a model of a light-emitting element of the present invention.

FIGS. 7A and 7B are diagrams illustrating a light-emitting device of the present invention.

FIG. 8 is a diagram illustrating a light-emitting device of the present invention.

FIG. 9 is a diagram illustrating a light-emitting device of the present invention.

FIG. 10 is a diagram illustrating a light-emitting device of the present invention.

FIG. 11 is a diagram illustrating a light-emitting device of the present invention.

FIGS. 12A and 12B are diagrams each showing an electronic device to which the present invention is applied.

FIGS. 13A and 13B are diagrams showing a module to which the present invention is applied.

FIG. 14 is a diagram showing an electronic device to which the present invention is applied.

FIGS. 15A to 15E are diagrams each showing an electronic device to which the present invention is applied.

FIGS. 16A to 16C are top views of light-emitting devices of the present invention.

FIGS. 17A and 17B are top views of light-emitting devices of the present invention.

FIG. 18 is a diagram illustrating an electronic device to which the present invention is applied.

FIG. 19 is a diagram illustrating a light-emitting device of the present invention.

FIG. 20 is a diagram illustrating a light-emitting element of the present invention.

FIGS. 21A and 21B are diagrams illustrating a light-emitting device of the present invention.

FIG. 22 is a diagram illustrating an electronic device to which the present invention is applied.

FIG. 23 is a diagram illustrating an electronic device to which the present invention is applied.

FIG. 24 is a diagram illustrating an electronic device to which the present invention is applied.

FIGS. 25A to 25C are diagrams illustrating light-emitting devices of the present invention.

FIGS. 26A and 2613 are diagrams each illustrating a light-emitting device of the present invention.

FIGS. 27A and 27B are diagrams illustrating a light-emitting device of the present invention.

### BEST MODE FOR CARRYING OUT THE INVENTION

Embodiment modes of the present invention will be hereinafter described in detail with reference to the accompanying drawings. However, the present invention is not limited to the following description. As is easily known to a person skilled in the art, the mode and the detail of the invention can be variously changed without departing from the spirit and the scope of the present invention. Therefore, the present invention should not be interpreted as being limited to the following description of the embodiment modes. Note that the same portions or portions having similar functions are commonly denoted by the same reference numerals in different drawings, and repetitive description thereof is omitted.

### Embodiment Mode 1

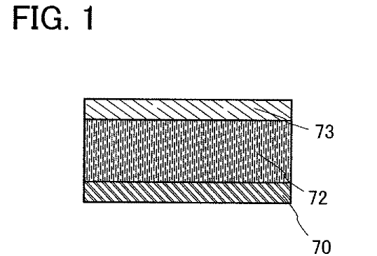

An object of this embodiment mode is to provide a light-emitting element which can be driven at low voltage, consumes less power, and enables chromaticity to be adjusted precisely. A light-emitting element in this embodiment mode will be described in detail with reference to FIGS. 1 to 6.

A feature of the light-emitting element of the present invention is to have an EL layer provided with a light-emitting layer, which includes an inorganic light-emitting material containing a mixed-valence compound, between a pair of electrode layers.

Inorganic EL elements are classified into a dispersion type inorganic EL element and a thin-film type inorganic EL element, depending on their element structures. The former and the latter are different in that the former has a light-emitting layer where particles of a light-emitting material are dispersed in a binder whereas the latter has a light-emitting layer formed of a thin film of a light-emitting material. However, the former and the latter have in common that electrons accelerated by a high electric field are necessary. It is to be noted that, as a mechanism of light emission to be obtained, there are donor-acceptor recombination type light emission that utilizes a donor level and an acceptor level, and localized type light emission that utilizes inner-shell electron transition of a metal ion. In general, in many cases, a dispersion-type inorganic EL element generates donor-acceptor recombination type light emission, and a thin-film type inorganic EL element generates localized type light emission.

The light-emitting element of the present invention will be described with reference to a conceptual diagram of FIG. 1. In FIG. 1, a light-emitting layer contains an inorganic light-emitting material, without referring to the type of the light-emitting layer, and both a dispersion-type inorganic EL element and a thin-film type inorganic EL element are included.

FIG. 1 shows a light-emitting element where an EL layer having a light-emitting layer 72 is provided between a first electrode layer 70 and a second electrode layer 73. Because the light-emitting element of FIG. 1 has a structure in which the EL layer does not have an insulating Layer or the like, the EL layer and the light-emitting layer 72 refer to the same layer. In the present invention, the light-emitting layer 72 includes an inorganic light-emitting material containing a mixed-valence compound.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

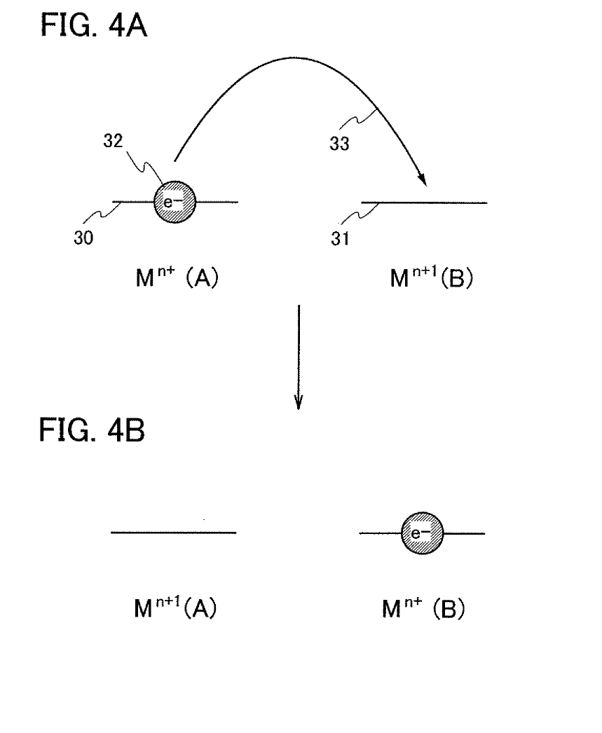

Hopping conduction occurs in a mixed-valence compound because it has different valences. FIGS. 4A and 4B are theoretical diagrams of hopping conduction in the mixed-valence compound of the present invention. FIGS. 4A and 4B show an electron exchange reaction between an atom M(A) having a +n valence and an atom M(B) having a +(n+1) valence. Since the atom M(A) is Mⁿ⁺(A) having a +n valence, it has an electron 32 at a level 30. On the other hand, since the atom M(B) is Mⁿ⁺¹(B) having a +(n+1) valence, it has no electron at a level 31.

The electron 32 is excited to hop, as indicated by an arrow 33, to the level 31 of the atom M(B), which is hopping conduction (see FIG. 4A). After the hopping conduction, the atom M(A) is Mⁿ⁺¹(A) having a +(n+1) valence since it has no electron at the level 30 of the atom M(A); on the other hand, the atom M(B) is Mⁿ(B) having a +n valence since it has the electron 32 at the level 31 of the atom M(B) (see FIG. 4B). In this manner, hopping conduction occurs.

Such hopping conduction can thus improve charge (carrier) mobility. Therefore, when an inorganic light-emitting material containing a mixed-valence compound is included in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

An inorganic light-emitting material that can be used in the present invention includes a base material and an impurity element which serves as a light-emission center. By changing impurity elements to be included, various colors of light emission can be performed. It is needless to say that the base material may emit light. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least one of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound.

In this specification, relative to a base material, an impurity element serving as a light-emission center is referred to as an activator, and another impurity element that is further added is referred to as a secondary activator. A first impurity element which forms a donor level is also referred to as a coactivator, and a light-emitting material containing a second impurity element which forms an acceptor level is also referred to as an activator. In an inorganic light-emitting material, an impurity element serving as a secondary activator may also be a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When the impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state or may be generated in such a manner that a given valence state is excited and energy is transferred to another or the other valance state (or another or the other impurity element), and the valence state gaining the energy emits light.

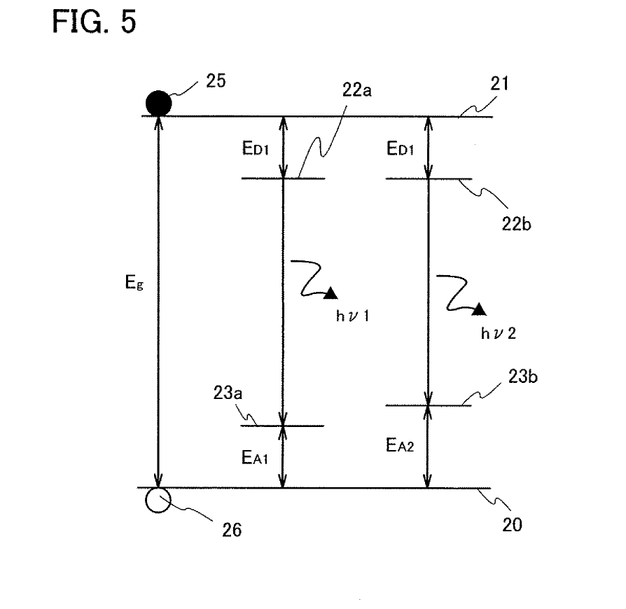

FIG. 5 is a theoretical diagram of a light-emitting mechanism in a light-emitting element provided with a light-emitting layer which includes a base material, a first impurity element which forms a donor level, and a second impurity element which forms an acceptor level and in which the second impurity element is a mixed-valence compound. FIG. 5 shows an energy state after the second impurity element which forms an acceptor level is excited and crystal field splitting occurs in an atom.

A hole 26 is in the valence band of a base material and an electron 25 is in the conduction band. When a band gap of the base material is Eg that is from a level 20 in the valence band to a level 21 in the conduction band, the first impurity element which forms a donor level has levels 22a and 22b with an energy gap of E_{D1} from the level 21 in the conduction band even in different atoms because the first impurity element is in a state with a single valence. On the other hand, because the second impurity element which forms an acceptor level is in a mixed-valence state, the strength of crystal field is changed and the second impurity element has a plurality of different levels, that is, a level 23a and a level 23b with energy gaps of E_{A1} and E_{A2} (E_{A1}<E_{A2}) from the level 21 in the conduction band, respectively. Because the acceptor level varies, i.e., the levels 23a and 23b in a case of donor-acceptor recombination type light emission, emission energy varies, i.e., energies hν1 and hν2 and light obtained has not only one but two wavelengths. As a result, the spectrum of emission wavelengths is broad or has two peaks. This similarly applies to a case where the first impurity element which forms a donor level is in a mixed-valence state and a case where each of the first impurity element which forms a donor level and the second impurity element which forms an acceptor level is in a mixed-valence state, and the spectrum of emission wavelengths is accordingly broad or has two peaks. Accordingly, chromaticity of emission color of a light-emitting element can be adjusted. Furthermore, white light emission is also possible with a combination of complementary colors. Thus, the range of selection of emission color is expanded.

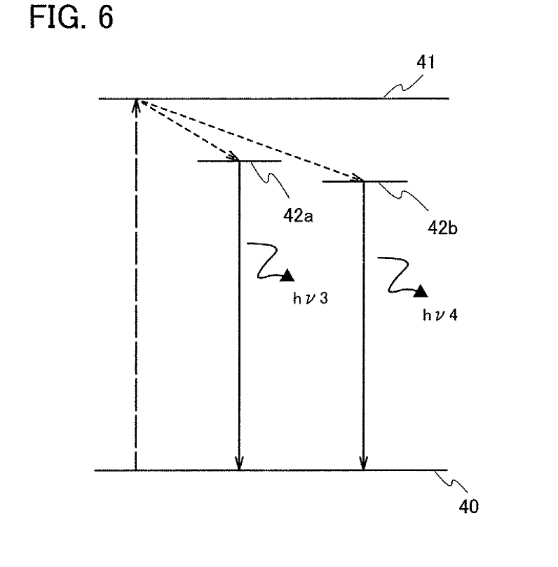

FIG. 6 is a theoretical diagram of a light-emitting mechanism for localized type light emission that utilizes inner-shell electron transition of metal ions, in a light-emitting element provided with a light-emitting layer which includes a base material and an impurity element serving as a light-emission center and in which the impurity element serving as a light-emission center is a mixed-valence compound. FIG. 6 shows an energy level of an impurity element serving as a light-emission center which is excited by hot electrons or the like.

When the impurity element in the mixed-valence state has two valences, the emission level can be at two different levels, that is, levels 42a and 42b. Because energy excited to an excitation level 41 returns from the two emission levels, that is, the levels 42a and 42b to a ground level 40 that is in a ground state, emission energy varies, i.e., energies hν3 and hν4 and light obtained has not only one wavelength but two wavelengths. As a result, the spectrum of emission wavelengths is broad or has two peaks. Examples of light-emitting materials that emit green light are as follows: a material which includes MgGa₂O₄ as a base material and Mn as an impurity element (MgGa₂O₄:Mn²⁺); and a material which includes Zn₂SiO₄ as a base material and Mn as an impurity element (Zn₂SiO₄:Mn²⁺). When Mn is in a mixed-valence state and has valences, i.e., Mn³⁺ and Mn⁴⁺, it is considered that the spectrum of green light emission wavelengths is broad or has two peaks.

In a case where a base material is ZnS and impurity elements are Cu and Mn (ZnS:Cu,Mn), when Cu is in a mixed-valence state, Cu⁺¹ and Cu⁺² exist. At this time, it is said that excitation energy of Cu is transferred to Mn and Mn emits light. Light emitted at this time has an emission wavelength spectrum of Mn, but because Cu has a +1 valence and a +2 valence, an increase in charge mobility of the base material and an increase in efficiency of energy transfer to Mn are expected. On the other hand, there is a case where Mn is in a mixed-valence state, and it is said that Mn has a plurality of emission levels and an emission spectrum is broad or has two peaks due to a difference between the emission levels.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly) chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows. Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function.

Furthermore, a material in a mixed-valence state, which can be used in the present invention, is specifically described. It is acceptable as long as an element that can be in a mixed-valence state is a metal element that can have a plurality of ion valences and has a large number of electrons; in particular, a transition metal or a rare earth metal is preferable. Examples of the metal element are typical elements belonging to Groups 13 to 15 of the periodic table, such as gallium (Ga), indium (In), thallium (Tl), tin (Sn), lead (Pb), and bismuth (Bi). Examples of the transition metal are elements belonging to Groups 4 to 12 of the periodic table, such as titanium (Ti), vanadium (V), chromium (Cr), manganese (Mn), iron (Fe), cobalt (Co), nickel (Ni), copper (Cu), niobium (Nb), molybdenum (Mo), ruthenium (Ru), rhodium (Rh), palladium (Pd), tungsten (W), rhenium (Re), iridium (Ir), platinum (Pt), and gold (Au). The rare earth metal refers to a lanthanoid or an actinoid of the periodic table, such as lantern (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), or ytterbium (Yb).

Examples of mixed-valence compounds that can be used as a base material in a light-emitting material or that can be used in the present invention as a base material when the base material itself emits light are halides, oxides, sulfides, and the like.

Examples of oxides are LiWO₃, Pb₃O₄, CeVO₄, Sb₂O₄, Mn₃O₄, CuMn₂O₄, CO₃O₄, Zn_{X}Mn_{1-X}O, IrO₂, LaNiO₃, NiO, V₂O₅, MoO₃, WO₃, CaWO₄, YVO₄, Fe₃O₄, NiFe₂O₄, MnFe₂O₄, NaV₂O₅, Eu₃O₄, LiTi₂O₄, SrTiO₃, YBa₂Cu₃O₇, LiV₂O₅, and the like. Examples of sulfides are GaS, CuS, WS₂, Eu₃S₄, Yb₃S₄, TIS, and the like. Examples of halides, when a halogen element is represented by X, are InX₂, GaX₂, TlX₂, Ta₆Cl₁₅, Tl₄Cl₆, and the like. It is to be noted that manganese oxide (Mn₃O₄) and cupper sulfide (CuₓS) (x is in the range of 1 to 2) are more preferable. Examples of nitrides are InN, SnN, and the like and other examples are Eu₃As₄, Yb₃As₄, and the like.

The above-mentioned element can also be used when a mixed-valence element is used as an impurity element serving as a light-emission center. For example, a base material MX where a first impurity element (D) which forms a donor level and a second impurity element (A) which forms an acceptor level are added as impurity elements is expressed as MX:D,A. In this case, the first impurity element (D) which forms a donor level and the second impurity element (A) which forms an acceptor level, contribute to light emission. A light-emitting material may contain one or more mixed-valence elements, and examples of light-emitting materials, which contain a mixed-valence element as a base material or which contain a mixed-valence element as an impurity element serving as a light-emission center, are as follows. It is needless to say that each of the base material and the impurity element serving as a light-emission center may be a mixed-valence compound (mixed-valence element). Examples of inorganic light-emitting materials that can be used in the present invention are as follows: ZnS:Cu; ZnO:Cu; Y₂O₃:Eu; SiAlON:Eu; MgGa₂O₄:Mn; ZnS:Fe; MgS:Eu; SrS:Sm; CaS:Eu; ZnS:Tm; ZnS:Tb; CaGa₂S₄:Ce; SrGa₂S₄:Ce; CaGa₂S₄:Ce; SrGa₂S₄:Ce; Zn₂SiO₄:Mn; YVO₄:Eu; ZnS:Mn; Zn_{X}Mg_{1-X}S:Cu, Cl; SrS:Cu; and the like. Some of oxides or sulfides are in a mixed-valence state when oxygen defect or sulfur defect is generated.

Whether or not a compound is in a mixed-valence state can be examined by any one of several techniques such as an optical method, an electrochemical method, and an X-ray crystallographic method. For example, the existence of a plurality of valences contained in a compound can be observed from the absorbing state of an observed atom in the compound by Moessbauer spectroscopy, magnetic susceptibility, X-ray absorption near edge structure (XANES) spectroscopy, X-ray absorption fine structure (XAFS) spectroscopy, or the like. Alternatively, a mixed-valence state can be judged by high-definition X-ray analysis, X-ray photoelectron spectroscopy (XPS), Auger electron spectroscopy (AES), or the like.

In the present invention, an insulating layer may be provided in addition to a light-emitting layer which generates light emission (which is a light-emitting region). A plurality of insulating layers may be provided, or the insulating layer itself may be a stacked layer of different thin films.

The light-emitting material that can be used in the present invention includes a base material and an impurity element which serves as a light-emission center. By changing impurity elements to be included, light emission of various colors can be obtained. As a method for forming the light-emitting material, any of various methods such as a solid phase method and a liquid phase method (a coprecipitation method) can be used. Further, an evaporative decomposition method, a double decomposition method, a method by heat decomposition reaction of a precursor, a reversed micelle method, a method in which such a method is combined with high-temperature baking, a liquid phase method such as a lyophilization method, or the like can also be used.

A solid phase method is a method in which a base material, and an impurity element or a compound containing an impurity element are weighed, mixed in a mortar, heated in an electric furnace, and baked to be reacted, whereby the impurity element is contained in the base material. The baking temperature is preferably 600° C. to 1500° C. This is because the solid-phase reaction does not progress when the temperature is too low, whereas the base material is decomposed when the temperature is too high. The baking may be performed in a powder state; however, it is preferable to perform the baking in a pellet state. Although the baking needs to be performed at relatively high temperature, the solid phase method is easy; thus, the solid phase method has high productivity and is suitable for mass production.

A liquid phase method (coprecipitation method) is a method in which a base material or a compound containing a base material is reacted with an impurity element or a compound containing an impurity element in a solution, dried, and then baked. Particles of a light-emitting material are distributed uniformly, and the reaction can progress even when the grain size is small and the baking temperature is low.

When a mixed-valence compound is used as an impurity element, as a base material used for a light-emitting material, a sulfide, an oxide, or a nitride can be used. Examples of sulfides are zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), and the like. Examples of oxides are zinc oxide (ZnO), yttrium oxide (Y₂O₃), and the like. Examples of nitrides are aluminum nitride (AlN), gallium nitride (GaN), indium nitride (InN), and the like. Other examples are zinc selenide (ZnSe), zinc telluride (ZnTe), and the like, and ternary mixed crystals such as calcium-gallium sulfide (CaGa₂S₄), strontium-gallium sulfide (SrGa₂S₄), and barium-gallium sulfide (BaGa₂S₄).

When a mixed-valence compound is used as a base material, as a light-emission center of localized type light emission, manganese (Mn), copper (Cu), samarium (Sm), terbium (Tb), erbium (Er), thulium (Tm), europium (Eu), cerium (Ce), praseodymium (Pr), or the like can be used. It is to be noted that a halogen element such as fluorine (F) or chlorine (Cl) may be added. The halogen element can be used as charge compensation.

When a mixed-valence compound is used as a base material, as a light-emission center of donor-acceptor recombination type light emission, a light-emitting material that includes a first impurity element which forms a donor level and a second impurity element which forms an acceptor level can be used. As the first impurity element, for example, fluorine (F), chlorine (Cl), aluminum (Al), or the like can be used. As the second impurity element, for example, copper (Cu), silver (Ag), or the like can be used.

In a case where a light-emitting material for donor-acceptor recombination type light emission is synthesized by a solid phase method, the base material, the first impurity element or a compound containing the first impurity element, and the second impurity element or a compound containing the second impurity element are each weighed, mixed in a mortar, heated in an electric furnace, and baked. As the base material, any of the above-described base materials can be used. As the first impurity element or the compound containing the first impurity element, for example, fluorine (F), chlorine (Cl), aluminum sulfide (Al₂S₃), or the like can be used. As the second impurity element or the compound containing the second impurity element, for example, copper (Cu), silver (Ag), copper sulfide (Cu₂S), silver sulfide (Ag₂S), or the like can be used. The baking temperature is preferably 600° C. to 1500° C. This is because the solid-phase reaction does not progress when the temperature is too low, whereas the base material is decomposed when the temperature is too high. It is to be noted that, although the baking may be performed in a powder state, it is preferable to perform the baking in a pellet state.

As the impurity element in the case of utilizing solid-phase reaction, a compound of the first impurity element and the second impurity element may be used. In this case, since the impurity element is easily diffused and solid-phase reaction progresses easily, a uniform light-emitting material can be obtained. Further, since an unnecessary impurity element does not enter, a light-emitting material having high purity can be obtained. As the compound of the first impurity element and the second impurity element, for example, copper chloride (CuCl), silver chloride (AgCl), or the like can be used.

It is to be noted that the concentration of each impurity element may be 0.01 mol % to 10 mol % with respect to the base material, and is preferably 0.03 mol % to 3 mol %.

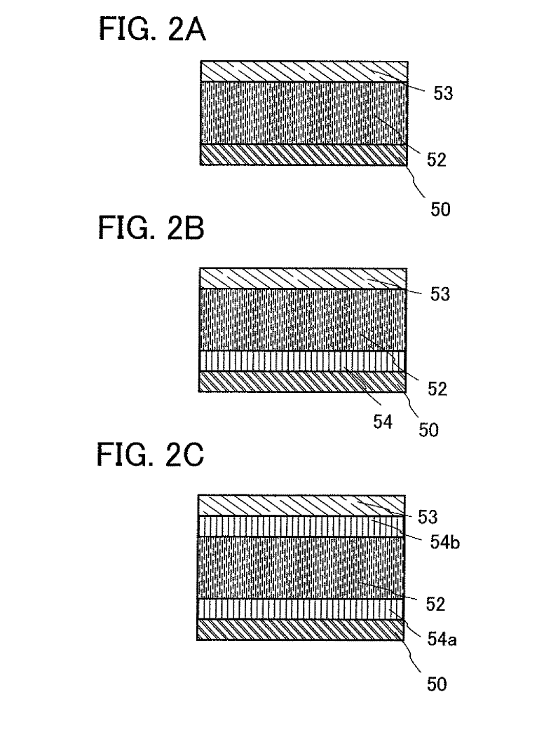

FIGS. 2A to 2C each show an example of a thin-film type inorganic EL element that can be used as a light-emitting element. In each of FIGS. 2A to 2C, a light-emitting element has a first electrode layer 50, a light-emitting layer 52, and a second electrode layer 53. In each of FIGS. 2A to 2C, the light-emitting layer 52 is formed to include an inorganic light-emitting material containing a mixed-valence compound.

The light-emitting elements shown in FIGS. 2B and 2C each have a structure where an insulating layer is provided between the electrode layer and the light-emitting layer of the light-emitting element of FIG. 2A. The Light-emitting element shown in FIG. 2B has an insulating layer 54 between the first electrode layer 50 and the light-emitting layer 52. The light-emitting element shown in FIG. 2C has an insulating layer 54a between the first electrode layer 50 and the light-emitting layer 52 and an insulating layer 54b between the second electrode layer 53 and the light-emitting layer 52. In this manner, the insulating layer may be provided between the light-emitting layer and one of the electrode layers that sandwich the light-emitting layer, or the insulating layer may be provided between the light-emitting layer and the first electrode layer and between the light-emitting layer and the second electrode layer. Moreover, the insulating layer may be a single layer or a stacked layer including a plurality of layers.

Although in FIG. 2B the insulating layer 54 is provided so as to be in contact with the first electrode layer 50, the insulating layer 54 may be provided so as to be in contact with the second electrode layer 53 by reversing the order of the insulating layer and the light-emitting layer.

In the case of a thin-film type inorganic EL element, a light-emitting layer is a layer containing the above-mentioned light-emitting material, which can be formed by a vacuum evaporation method such as a resistance heating evaporation method or an electron beam evaporation (EB evaporation) method, a physical vapor deposition (PVD) method such as a sputtering method, a chemical vapor deposition (CVD) method such as a metal organic CVD method or a low-pressure hydride transport CVD method, an atomic layer epitaxy (ALE) method, or the like.

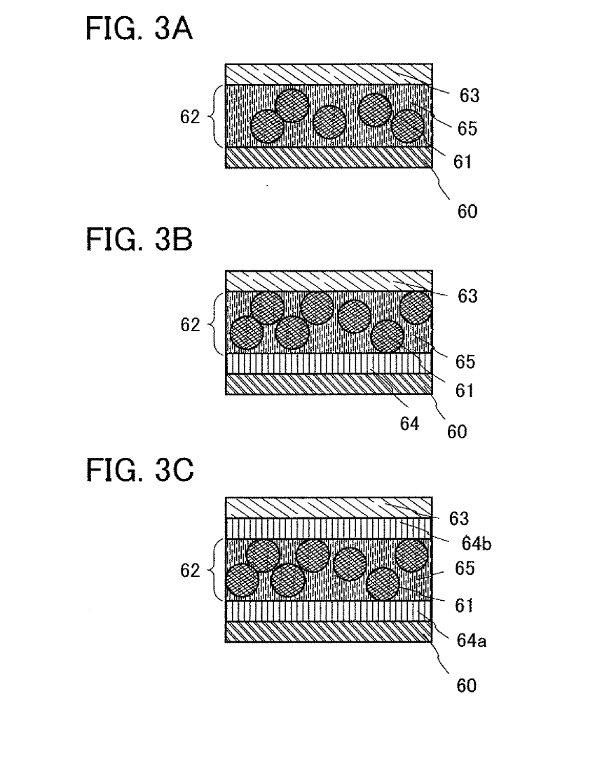

FIGS. 3A to 3C each show an example of a dispersion-type inorganic EL element that can be used as a light-emitting element. In FIG. 3A, a light-emitting element has a stacked-layer structure of a first electrode layer 60, a light-emitting layer 62, and a second electrode layer 63, where a light-emitting material 61 held by a binder is contained in the light-emitting layer 62. In each of FIGS. 3A to 3C, the light-emitting layer 62 is formed to include an inorganic light-emitting material containing a mixed-valence compound.

The light-emitting elements shown in FIGS. 3B and 3C each have a structure where an insulating layer is provided between the electrode layer and the light-emitting layer of the light-emitting element of FIG. 3A. The light-emitting element shown in FIG. 3B has an insulating layer 64 between the first electrode layer 60 and the light-emitting layer 62. The light-emitting element shown in FIG. 3C includes an insulating layer 64a between the first electrode layer 60 and the light-emitting layer 62 and an insulating layer 64b between the second electrode layer 63 and the light-emitting layer 62. In this manner, the insulating layer may be provided between the light-emitting layer and one of the electrode layers that sandwich the light-emitting layer, or the insulating layer may be provided between the light-emitting layer and the first electrode layer and between the light-emitting layer and the second electrode layer. Moreover, the insulating layer may be a single layer or a stacked layer including a plurality of layers.

Although in FIG. 3B the insulating layer 64 is provided so as to be in contact with the first electrode layer 60, the insulating layer 64 may be provided so as to be in contact with the second electrode layer 63 by reversing the order of the insulating layer and the light-emitting layer.

In the case of a dispersion-type inorganic EL element, a film-like light-emitting layer where particles of a light-emitting material are dispersed in a binder is formed. When particles with a desired grain size cannot be obtained by a manufacturing method of a light-emitting material, a light-emitting material may be processed into particles by being crushed in a mortar or the like. The binder refers to a substance for fixing particles of a light-emitting material in a dispersed state to keep a shape of a light-emitting layer. The light-emitting material is uniformly dispersed and fixed in the light-emitting layer by the binder.

In the case of a dispersion-type inorganic EL element, a light-emitting layer can be formed by a droplet discharging method which can selectively form a light-emitting layer, a printing method (such as screen printing or offset printing), a coating method such as a spin coating method, a dipping method, a dispenser method, or the like. There are no particular limitations on the thickness of the light-emitting layer; however, a thickness of 10 nm to 1000 nm is preferable. In addition, in the light-emitting layer containing a light-emitting material and a binder, the proportion of the light-emitting material is preferably set to be 50 wt % to 80 wt %.

As the binder that can be used in this embodiment mode, an organic material or an inorganic material can be used, or a mixed material of an organic material and an inorganic material may also be used. As the organic material, a resin such as a polymer having a relatively high dielectric constant like a cyanoethyl cellulose-based resin, polyethylene, polypropylene, a polystyrene-based resin, a silicone resin, an epoxy resin, or vinylidene fluoride can be used. Alternatively, a heat-resistant high molecular compound such as aromatic polyamide or polybenzimidazole, or a siloxane resin may be used. A siloxane resin corresponds to a resin containing a Si—O—Si bond. Siloxane has a skeleton structure formed by the bond of silicon (Si) and oxygen (O). As a substituent thereof, an organic group containing at least hydrogen (such as an alkyl group or aryl group) is used. Alternatively, a fluoro group may be used as the substituent. Further, a fluoro group and an organic group containing at least hydrogen may be used as the substituent. Moreover, the following resin material may also be used: a vinyl resin such as polyvinyl alcohol or polyvinyl butyral; a phenol resin; a novolac resin; an acrylic resin; a melamine resin; a urethane resin; an oxazole resin (polybenzoxazole); or the like. A dielectric constant can be adjusted by appropriately mixing high dielectric constant fine particles of barium titanate (BaTiO₃), strontium titanate (SrTiO₃), or the like in the above resin.

As the inorganic material contained in the binder, a material such as silicon oxide (SiO_{X}), silicon nitride (SiN_{X}), silicon containing oxygen and nitrogen, aluminum nitride (AlN), aluminum containing oxygen and nitrogen, aluminum oxide (Al₂O₃), titanium oxide (TiO₂), BaTiO₃, SrTiO₃, lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), zirconium oxide (ZrO₂), ZnS, and other substances containing an inorganic material can be used. By mixing the organic material with a high-dielectric constant inorganic material (by addition or the like), a dielectric constant of a light-emitting layer containing a light-emitting material and a binder can be better controlled and further increased.

In a manufacturing process, the light-emitting material is diffused in a solution containing a binder. As a solvent of the solution containing a binder that can be used in this embodiment mode, it is preferable to select such a solvent that allows a binder material to dissolve and can make a solution with the viscosity which is appropriate for a method for forming the light-emitting layer (various wet processes) and a desired film thickness. An organic solvent or the like can be used, and for example, when a siloxane resin is used as the binder, propylene glycolmonomethyl ether, propylene glycolmonomethyl ether acetate (also called PGMEA), 3-methoxy-3-methyl-1-butanol (also called MMB), or the like can be used.

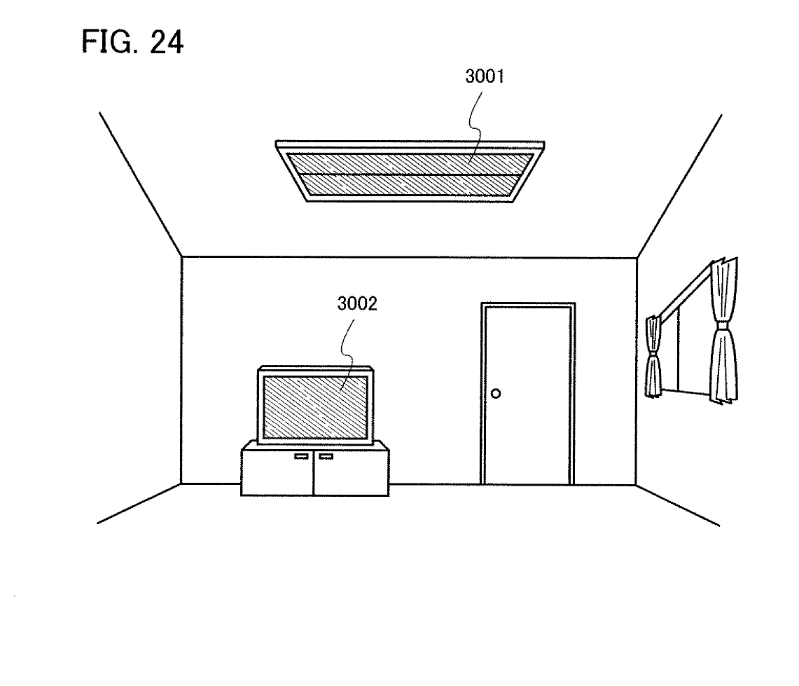

Although there are no particular limitations on insulating layers such as the insulating layers 54, 54a, and 54b in FIGS. 2B and 2C and the insulating layers 64, 64a, and 64b in FIGS. 24B and 24C, such insulating layers preferably have high dielectric strength and dense film qualities, and more preferably have a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like, or a mixed film or a staked layer film of two or more kinds of them can be used. These insulating films can be formed by sputtering, evaporation, CVD, or the like. In addition, the insulating layers may be formed by dispersing particles of these insulating materials in the binder. The binder material may be formed with the same material and by the same method as the binder contained in the light-emitting layer. The thickness of such an insulating layer is not particularly limited, and a film thickness of 10 nm to 1000 nm is preferable.

The light-emitting element described in this embodiment mode can emit light when a voltage is applied between the pair of electrode layers which sandwiches the light-emitting layer, and can operate by direct current driving or alternating current driving.

The light-emitting layer may have a structure to perform color display by providing pixels with light-emitting layers having different emission wavelength ranges. Typically, light-emitting layers corresponding to colors of R (red), C (green), and B clue) are formed. Also in this case, color purity can be improved and a pixel portion can be prevented from having a mirror surface (reflection) by providing the light-emitting side of the pixel with a filter which transmits light having an emission wavelength range of the light emitted from the pixel. By provision of a filter, a circularly polarizing plate or the like that has been conventionally considered to be necessary can be omitted, and further, the loss of light emitted from the light-emitting layer can be eliminated. Furthermore, a change in color tone, which occurs when a pixel portion (display screen) is obliquely seen, can be reduced.

Note that the light-emitting layer may be formed as a single layer or by stacking a plurality of layers. A layer structure of the light-emitting layer can be changed, and an electrode layer for injecting electrons may be provided or a light-emitting material may be dispersed, instead of providing any specific electron-injecting region or light-emitting region. Such a change can be permitted unless it departs from the spirit of the present invention.

A light emitting element formed using the above-described material emits light when biased forwardly. Pixels of a display device, which are formed using the light emitting elements, can be driven by a simple matrix mode or an active matrix mode. In either mode, each pixel is made to emit light by applying a forward bias thereto in specific timing, and the pixel is in a non-light-emitting state for a certain period. By applying a reverse bias at this non-light-emitting time, reliability of the light emitting element can be improved. In the light emitting element, there is a deterioration mode in which emission intensity is decreased under specific driving conditions or a deterioration mode in which a non-light-emitting region is enlarged in the pixel and luminance is apparently decreased. However, progression of deterioration can be slowed down by alternating driving. Thus, reliability of the light emitting display device can be improved. Either a digital drive or an analog drive can be employed.

A color filter (colored layer) may be formed over a sealing substrate. The color filter (colored layer) can be formed by an evaporation method or a droplet discharging method. High-resolution display can be performed with the use of the color filter (colored layer). This is because a broad peak can be corrected to be sharp in an emission spectrum of each of R, G, and B by the color filter (colored layer).

Full color display can be performed by the steps of forming a material that emits light of a single color and combining with a color filter or a color conversion layer. Preferably, the color filter (colored layer) or the color conversion layer is formed over, for example, a sealing substrate and attached to an element substrate.

Of course, display of a single color emission may also be performed. For example, an area color type display device may be manufactured using single color emission. The area color type is suitable for a passive matrix display portion, and can mainly display characters and symbols.

At least either the first electrode layers 50, 60, and 70 or the second electrode layers 53, 63, and 73, through which light is extracted, may be formed to have a light-transmitting property. When a light-transmitting conductive material is used for both of the first electrode layers and the second electrode layers, a dual emission structure can be provided, in which tight from the light-emitting element is emitted from both the first electrode layer 50, 60, and 70 side and the second electrode layer 53, 63, and 73 side.

For the first electrode layers 50, 60, and 70 and the second electrode layer 53, 63, and 73, indium oxide containing tungsten oxide, indium zinc oxide containing tungsten oxide, indium oxide containing titanium oxide, indium tin oxide containing titanium oxide, or the like can be used. Of course, indium tin oxide (ITO), indium zinc oxide (IZO), indium tin oxide to which silicon oxide is added (ITSO), or the like can also be used. Alternatively, a film containing as its main component an element such as Ti, Ni, W, Cr, Pt, Zn, Sn, In, Ta, Al, Cu, Au, Ag, Mg, Ca, Li, or Mo or an alloy material or a compound material containing the above element as its main component such as TiN, TiSi_{X}N_{Y}, WSi_{X}, WN_{X}, WSi_{X}N_{Y}, or NbN can be used.

In addition, even in the case of using a non-light-transmitting material such as the above-mentioned metal film, when the thickness is made to be thin (preferably, about 5 nm to 30 nm) so as to be able to transmit light, light can be emitted through the first electrode layers 50, 60, and 70 and the second electrode layers 53, 63, and 73.

Each of the first electrode layers 50, 60, and 70 and the second electrode layers 53, 63, and 73 can be formed by an evaporation method by resistance heating, an EB evaporation method, a sputtering method, a CVD method, a spin coating method, a printing method, a dispenser method, a droplet discharging method, or the like.

Because the light-emitting element of this embodiment mode has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage and can achieve a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 2

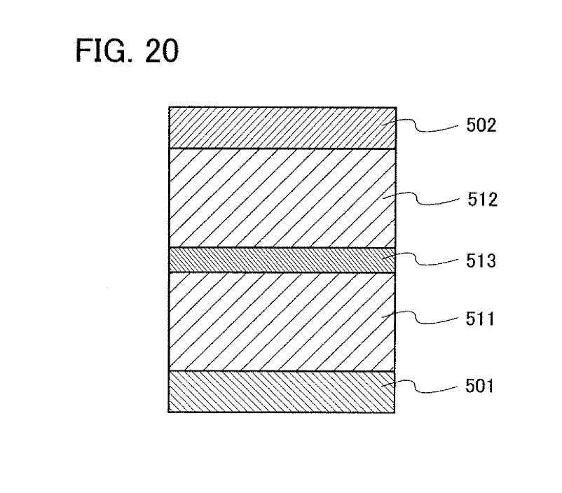

In this embodiment mode, a mode of a light-emitting element according to the present invention in which a plurality of light-emitting units are stacked (this light-emitting element is also referred to as a stacked-type element) will be described with reference to FIG. 20. This light-emitting element is a light-emitting element including a plurality of light-emitting units between a first electrode layer and a second electrode layer.

In FIG. 20, a first light-emitting unit 511 and a second light-emitting unit 512 are stacked between a first electrode layer 501 and a second electrode layer 502. The first electrode layer 501 and the second electrode layer 502 can be similar to the electrode layers described in Embodiment Mode 1. The first light-emitting unit 511 and the second light-emitting unit 512 may have either the same structure or different structures, which may be similar to those described in Embodiment Mode 1. Accordingly, a structure may be employed in which light-emitting layers provided in the first light-emitting unit 511 and the second light-emitting unit 512 include an inorganic light-emitting material containing a mixed-valence compound.

Each of the first light-emitting unit 511 and the second light-emitting unit 512 has a light-emitting layer which includes an inorganic light-emitting material containing a mixed-valence compound.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows: Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound of this embodiment mode using the present invention can be formed using the material described in Embodiment Mode 1.

An inorganic light-emitting material that can be used in this embodiment mode includes a base material and an impurity element which serves as a light-emission center. By changing impurity elements to be included, various colors of light emission can be performed. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least one of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound. In an inorganic light-emitting material, an impurity element serving as a secondary activator may also be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When an impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state of may be generated in such a manner that a given valence state is excited and energy is transferred to another or the other valance state (or another or the other impurity element), and the valence state gaining the energy emits light.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly, chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

A charge-generating layer 513 includes a composite material of an organic compound and a metal oxide. This composite material of an organic compound and a metal oxide includes, for example, an organic compound and a metal oxide such as V₂O₅, MoO₃, or WO₃. As the organic compound, any of various compounds such as an aromatic amine compound, a carbazole derivative, aromatic hydrocarbon, and a high molecular compound (e.g., oligomer, dendrimer, or polymer) can be used. As the organic compound, it is preferable to use an organic compound having a hole-transporting property, which has a hole mobility of 10⁻⁶ cm²/Vs or higher. However, other substances than these may also be used as long as the hole-transporting properties thereof are higher than the electron-transporting properties thereof. The composite material of the organic compound and the metal oxide can realize low-voltage driving and low-current driving because of its superior carrier injecting property and carrier transporting property.

Alternatively, the charge-generating layer 513 may be formed using a combination of the composite material of the organic compound and the metal oxide with another material. For example, a layer containing the composite material of the organic compound and the metal oxide may be combined with a layer containing a compound selected from substances having electron-donating properties and a compound having a high electron-transporting property. Moreover, a layer containing the composite material of the organic compound and the metal oxide may be combined with a transparent conductive film.

In any case, it is acceptable as long as the charge-generating layer 513 that is interposed between the first light-emitting unit 511 and the second light-emitting unit 512 injects electrons into one of these light-emitting units and holes to the other thereof when voltage is applied to the first electrode layer 501 and the second electrode layer 502.

In this embodiment mode, the light-emitting element having two light-emitting units has been described. However, the present invention can similarly be applied to a light-emitting element in which three or more light-emitting units are stacked. When a charge-generating layer is provided between a pair of electrode layers so as to partition a plurality of light-emitting units, like the light-emitting element of this embodiment mode, a long-life element in a high luminance region can be realized while current density is kept low. When the light-emitting element is applied to lighting, voltage drop due to resistance of an electrode material can be suppressed, thereby achieving homogeneous light emission in a large area. Moreover, a light-emitting device, which can be driven at low voltage and consumes less power, can be realized.

It is noted that this embodiment mode can be combined with Embodiment Mode 1 as appropriate.

Because the light-emitting element of this embodiment mode has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage and can achieve a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 3

In this embodiment mode, a structural example of a light-emitting device including the light-emitting element of the present invention will be described with reference to drawings. More specifically, the case where a structure of a light-emitting device is a passive matrix type will be described.

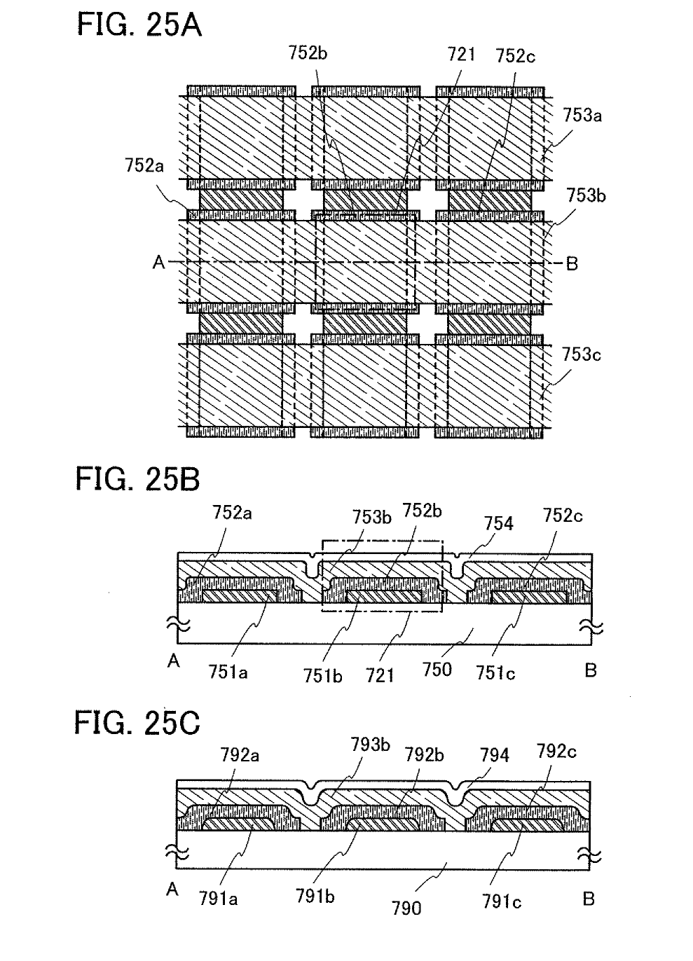

The light-emitting device includes, over a substrate 750, first electrode layers 751a, 751b, and 751c extending in a first direction; EL layers 752a, 752b, and 752c provided to cover the first electrode layers 751a, 751b, and 751c respectively; and second electrode layers 753a, 753b, and 753c extending in a second direction that is perpendicular to the first direction (see FIG. 25A). The EL layers 752a, 752b, and 752c each have a light-emitting layer which includes an inorganic light-emitting material containing a mixed-valence compound. The EL layers 752a, 752b, and 752c are provided between the first electrode layers 751a, 751b, and 751c and the second electrode layers 753a, 753b, and 753c. In addition, an insulating layer 754 functioning as a protective film is provided to cover the second electrode layers 753a, 753b, and 753c (see FIG. 25B).

FIG. 25C is a modified example of FIG. 25B. Over a substrate 790, there are first electrode layers 791a, 791b, and 791c, EL layers 792a, 792b, and 792c, a second electrode layer 793b, and an insulating layer 794 which is a protective layer. The EL layers 792a, 792b, and 792c each have a light-emitting layer which includes an inorganic light-emitting material containing a mixed-valence compound. As shown in FIG. 25C, the first electrode layers 791a, 791b, and 791c may have a tapered shape or a shape in which radius of curvature changes continuously. The shape like the first electrode layers 791a, 791b, and 791c can be formed by a droplet discharging method or the like. With such a curved surface having a curvature, coverage of an insulating layer or conductive layer to be stacked thereover is favorable.

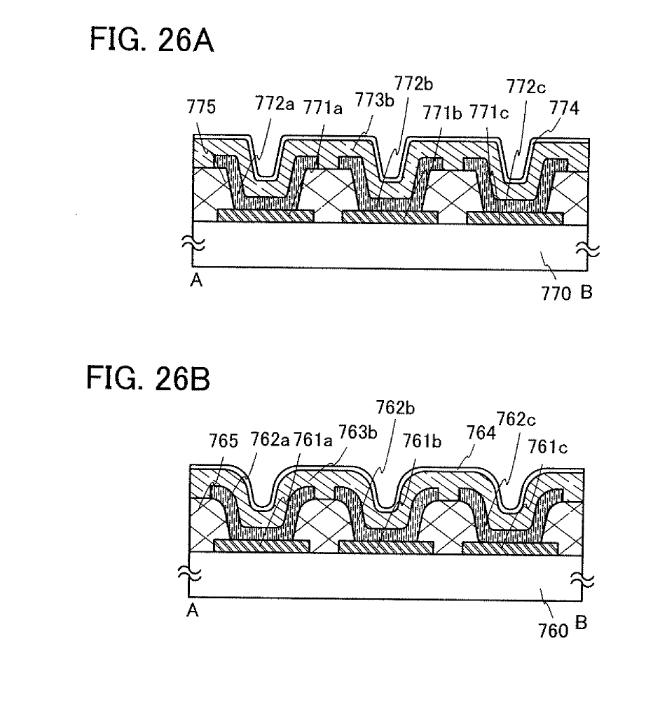

In addition, a partition wall (insulating layer) may be formed to cover the end portions of the first electrode layer. The partition wall (insulating layer) serves as a wall separating light-emitting elements from each other. FIGS. 26A and 26B each show a structure in which the end portions of the first electrode layer is covered with the partition wall (insulating layer).

In an example of a light-emitting element shown in FIG. 26A, a partition wall (insulating layer) 775 is formed into a tapered shape to cover end portions of first electrode layers 771a, 771b, and 771c. The partition wall (insulating layer) 775 is formed over the first electrode layers 771a, 771b, and 771c provided over a substrate 770, and EL layers 772a, 772b, and 772c, a second electrode layer 773b, and an insulating layer 774 are formed. The EL layers 772a, 772b, and 772c each have a light-emitting layer which includes an inorganic light-emitting material containing a mixed-valence compound.

An example of a light-emitting element shown in FIG. 26B has a shape in which a partition wall (insulating layer) 765 has a curvature, and radius of the curvature changes continuously. First electrode layers 761a, 761b, and 761c, EL layers 762a, 762b, and 762c, a second electrode layer 763b, and an insulating layer 764 provided over a substrate 760. The EL layers 762a, 762b, and 762c each have a light-emitting layer which includes an inorganic light-emitting material containing a mixed-valence compound.

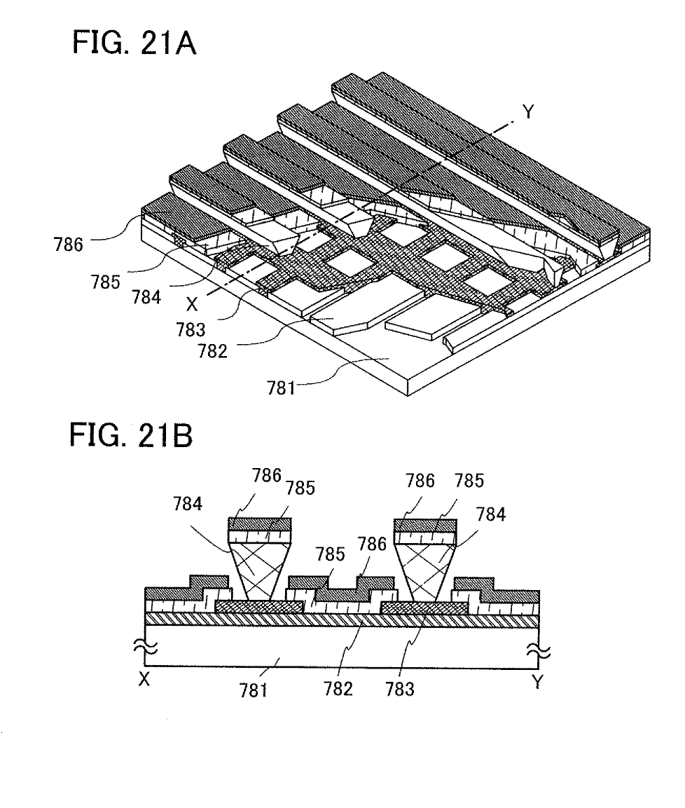

Another example of partition wall is shown in FIGS. 21A and 21B. FIG. 21A shows a perspective view of a passive matrix light-emitting device manufactured in accordance with the present invention, and FIG. 21B shows a cross-sectional view taken along a line X-Y in FIG. 21A. In FIGS. 21A and 21B, EL layers 785 are provided between first electrode layers 782 and second electrode layers 786 over a substrate 781. Each EL layer 785 has a light-emitting layer which includes an inorganic light-emitting material containing a mixed-valence compound. The end portions of each first electrode layer 782 are covered with an insulating layer 783. Partition walls (insulating layers) 784 are provided over the insulating layer 783. Each partition wall (insulating layer) 784 slopes so that a distance between one side wall and the other side wall becomes narrow toward the substrate surface. That is, a cross section taken along the direction of the short sides of the partition layer 784 is trapezoidal, and the base of the partition layer 784 (a side in the same direction as a plane direction of the insulating layer 783 and in contact with the insulating layer 783) is shorter than the upper side thereof (a side in the same direction as the plane direction of the insulating layer 783 and not in contact with the insulating layer 783). The partition wall (insulating layer) 784 provided in this manner can prevent the light-emitting element from being defective due to static electricity or the like.

The EL layers 752 (752a, 752b, 752c), 762 (762a, 762b, 762c), 772 (772a, 772b, 772c), 785, and 792 (792a, 792b, 792c) each have a light-emitting layer which includes an inorganic light-emitting material containing a mixed-valence compound. In addition, the EL layers may each have an insulating layer as described in Embodiment Mode 1 and as shown in FIG. 2A to 3C. The light-emitting element of this embodiment mode using the present invention can be specifically formed using the structure, material, and method that are described in Embodiment Mode 1.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows: Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound of this embodiment mode using the present invention can be formed using the material described in Embodiment Mode 1.

Furthermore, a material in a mixed-valence state, which can be used in this embodiment mode, is specifically described. It is acceptable as long as an element that can be in a mixed-valence state is a metal element that can have a plurality of ion valences and has a large number of electrons; in particular, a transition metal or a rare earth metal is preferable. Examples of the metal element are typical elements belonging to Groups 13 to 15 of the periodic table, such as gallium (Ga), indium (In), thallium (Tl), tin (Sn), lead (Pb), and bismuth (Bi). Examples of the transition metal are elements belonging to Groups 4 to 12 of the periodic table, such as titanium (Ti), vanadium (V), chromium (Cr), manganese (Mn), iron (Fe), cobalt (Co), nickel (Ni), copper (Cu), niobium (Nb), molybdenum (Mo), ruthenium (Ru), rhodium (Rh), palladium (Pd), tungsten (W), rhenium (Re), iridium (Ir), platinum (Pt), and gold (Au). The rare earth metal refers to a lanthanoid or an actinoid of the periodic table, such as lantern (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), or ytterbium (Yb).

Examples of mixed-valence compound that can be used as a base material in a light-emitting material or that can be used in the present invention as a base material when the base material itself emits light are halides, oxides, sulfides, and the like.

Examples of oxides are LiWO₃, Pb₃O₄, CeVO₄, Sb₂O₄, Mn₃O₄, CuMn₂O₄, Co₃O₄, Zn_{X}Mn_{1-X}O, IrO₂, LaNiO₃, NiO, V₂O₅, MoO₃, WO₃, CaWO₄, YVO₄, Fe₃O₄, NiFe₂O₄, MnFe₂O₄, NaV₂O₅, Eu₃O₄, LiTi₂O₄, SrTiO₃, YBa₂Cu₃O₇, LiV₂O₅, and the like. Examples of sulfides are GaS, CuS, WS₂, Eu₃S₄, Yb₃S₄, TIS, and the like. Examples of halides, when a halogen element is represented by X, are InX₂, GaX₂, TlX₂, Ta₆Cl₁₅, Tl₄Cl₆, and the like. Examples of nitrides are InN, SnN, and the like and other examples are Eu₃As₄, Yb₃As₄, and the like.

The above-mentioned element can also be used when a mixed-valence element is used as an impurity element serving as a light-emission center. For example, a base material MX where a first impurity element (D) which forms a donor level and a second impurity element (A) which forms an acceptor level are added as impurity elements is expressed as MX:D,A. In this case, the first impurity element (D) which forms a donor level and the second impurity element (A) which forms an acceptor level contribute to light emission. A light-emitting material may contain one or more mixed-valence elements, and examples of light-emitting materials, which contain a mixed-valence element as a base material or which contain a mixed-valence element as an impurity element serving as a light-emission center, are as follows. It is needless to say that each of the base material and the impurity element serving as a light-emission center may be a mixed-valence compound (mixed-valence element). Examples of inorganic light-emitting materials that can be used in the present invention are as follows: ZnS:Cu; ZnO:Cu; Y₂O₃:Eu; SiAlON:Eu; MgGa₂O₄:Mn; ZnS:Fe; MgS:Eu; SrS:Sm; CaS:Eu; ZnS:Tm; ZnS:Tb; CaGa₂S₄:Ce; SrGa₂S₄:Ce; CaGa₂S₄:Ce; SrGa₂S₄:Ce; Zn₂SiO₄:Mn; YVO₄:Eu; ZnS:Mn; ZnₓMg₁₋ₓS:Cu, Cl; SrS:Cu; and the like. Some of oxides or sulfides are in a mixed-valence state when oxygen defect or sulfur defect is generated.

An inorganic light-emitting material that can be used in this embodiment mode includes a base material and an impurity element which serves as a light-emission center. By changing impurity elements to be included, various colors of light emission can be performed. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least on of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound. In an inorganic light-emitting material, an impurity element serving as a secondary activator may also be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When an impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state or may be generated in such a manner that a given valence state is excited and energy is transferred to another or the other valance state (or another or the other impurity element), and the valence state gaining the energy emits light.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly, chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

A quartz substrate, a silicon substrate, a metal substrate, a stainless-steel substrate, or the like, in addition to a glass substrate and a flexible substrate, can be used as each of the substrates 750, 760, 770, 781, and 790. The flexible substrate is a substrate that can be bent, such as a plastic substrate formed using polycarbonate, polyarylate, polyether sulfone, or the like. In addition, a film (of polypropylene, polyester, vinyl, polyvinyl fluoride, vinyl chloride, or the like), paper made of a fibrous material, a base film (of polyester, polyamide, an inorganic evaporated film, paper, or the like), or the like can be used. Alternatively, the light-emitting element can be provided over a field effect transistor (FET) formed on a semiconductor substrate such as a Si substrate, or over a thin film transistor (also referred to as a TFT) formed over a substrate such as a glass substrate.

Any of the materials and methods of the first electrode layer, the second electrode layer, and the EL layer including the light-emitting layer, described in this embodiment mode, can be similar to those described in Embodiment Mode 1.

For the partition walls (insulating layers) 765, 775, and 784, silicon oxide, silicon nitride, silicon oxynitride, aluminum oxide, aluminum nitride, aluminum oxynitride, or other inorganic insulating materials; acrylic acid, methacrylic acid, or a derivative thereof; a heat-resistant high molecular compound such as polyimide, aromatic polyamide, or polybenzimidazole; or a siloxane resin may be used. Alternatively, the following resin material can be used: a vinyl resin such as polyvinyl alcohol or polyvinylbutyral; an epoxy resin; a phenol resin; a novolac resin; an acrylic resin; a melamine resin; a urethane resin; or the like. Further alternatively, an organic material such as benzocyclobutene, parylene, fluorinated arylene ether, or polyimide or the like may be used. A vapor deposition method such as a plasma CVD method or a thermal CVD method, or a sputtering method can be used as a formation method of the partition walls. A droplet discharging method or a printing method (a method by which a pattern can be formed, such as screen printing or offset printing) can also be used. A coating film or an SOG film obtained by a coating method or the like can also be used.

After a conductive layer, an insulating layer or the like is formed by discharge of a composition by a droplet discharging method, a surface thereof may be planarized by pressing with pressure in order to enhance planarity. The pressing may be performed as follows: unevenness is reduced by moving a roller-shaped object on the surface, a flat plate-shaped object is pressed against the surface, or the like. A heating step may also be performed at the time of the pressing. Alternatively, the unevenness of the surface may be removed with an air knife after the surface is softened or melted with a solvent or the like. A CMP method may also be used for polishing the surface. This step can be employed in planarizing the surface when unevenness is generated by a droplet discharging method.

Because the light-emitting element of this embodiment mode has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage and can achieve a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 4

In this embodiment mode, a light-emitting device having a structure that is different from that of Embodiment Mode 2 will be described. Specifically, the case where a structure of a light-emitting device is an active matrix type will be shown.

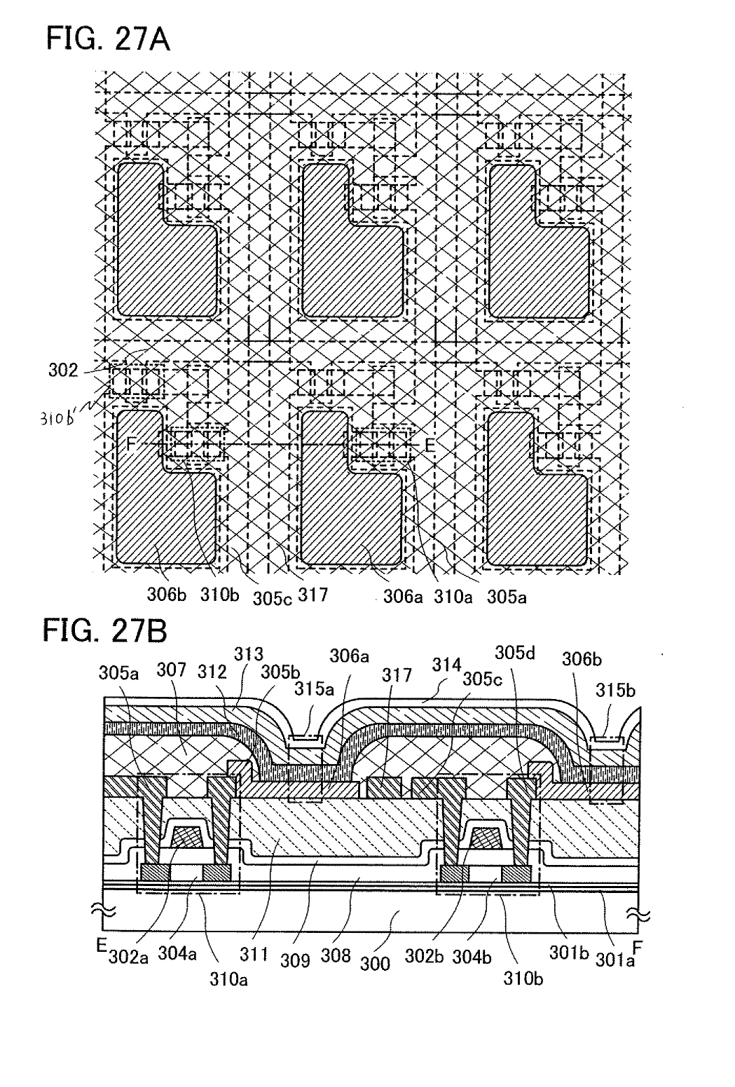

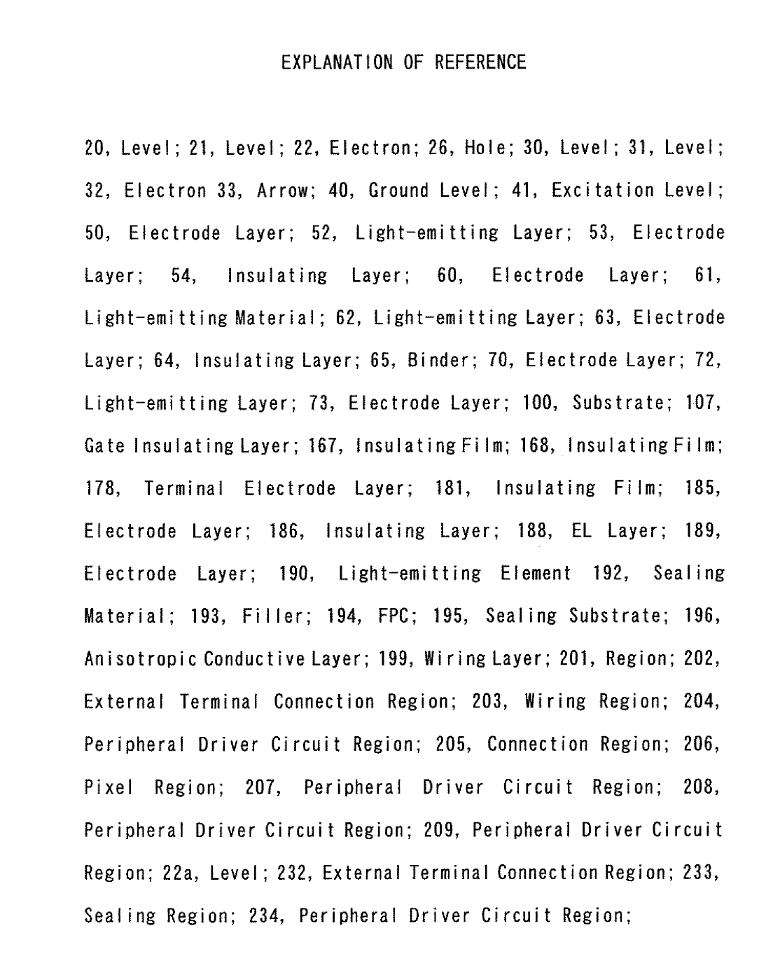

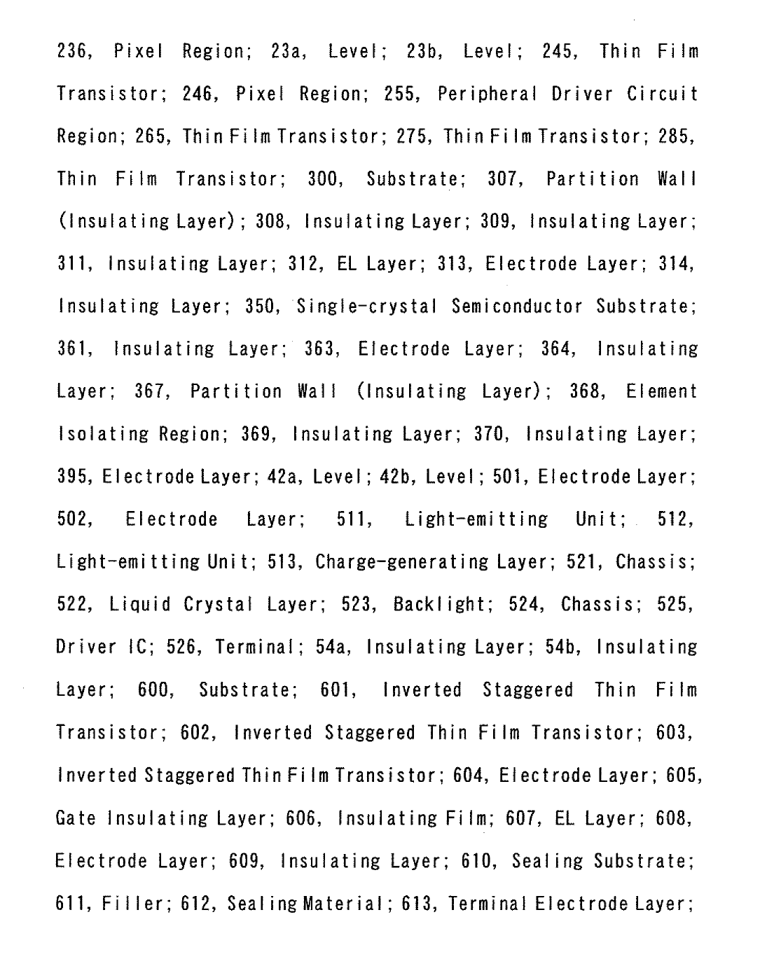

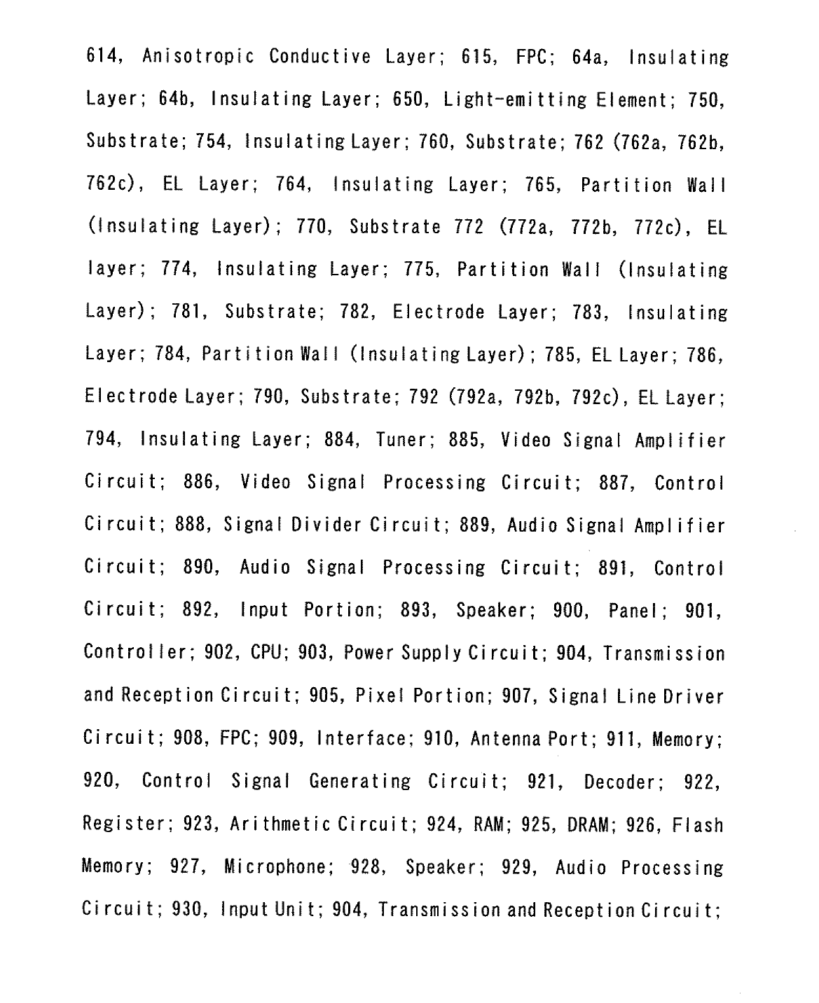

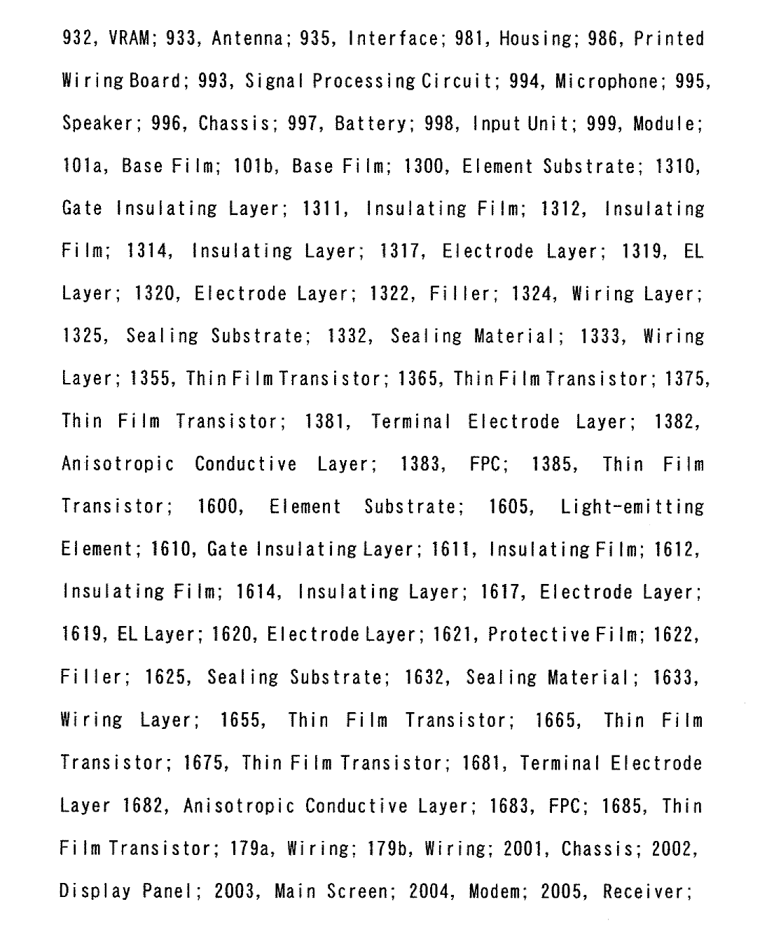

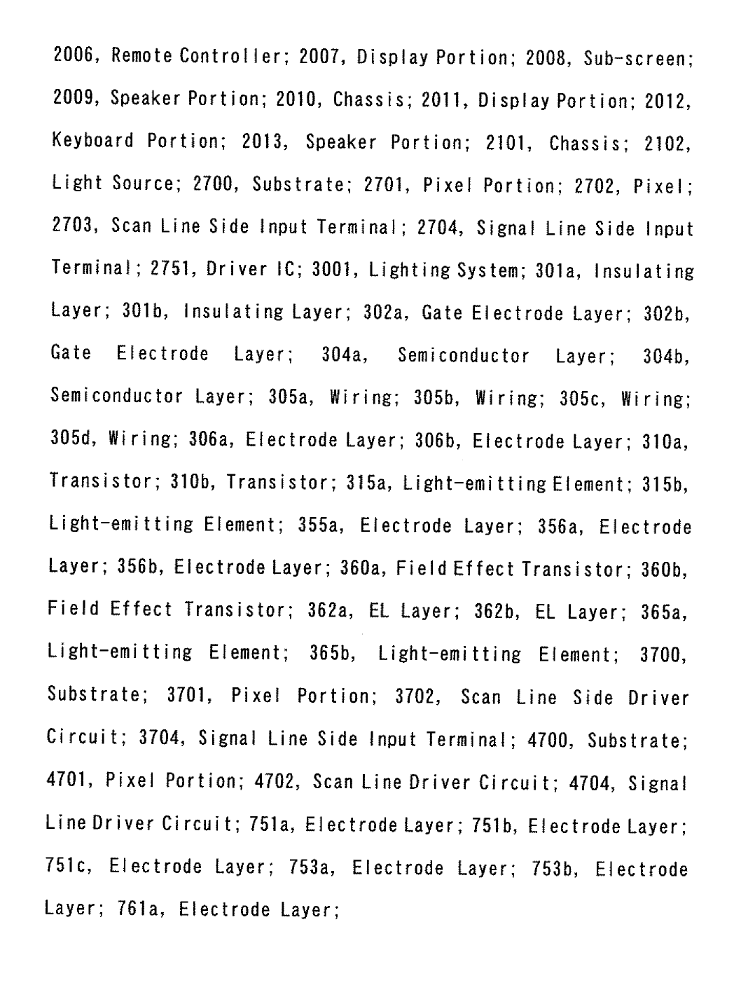

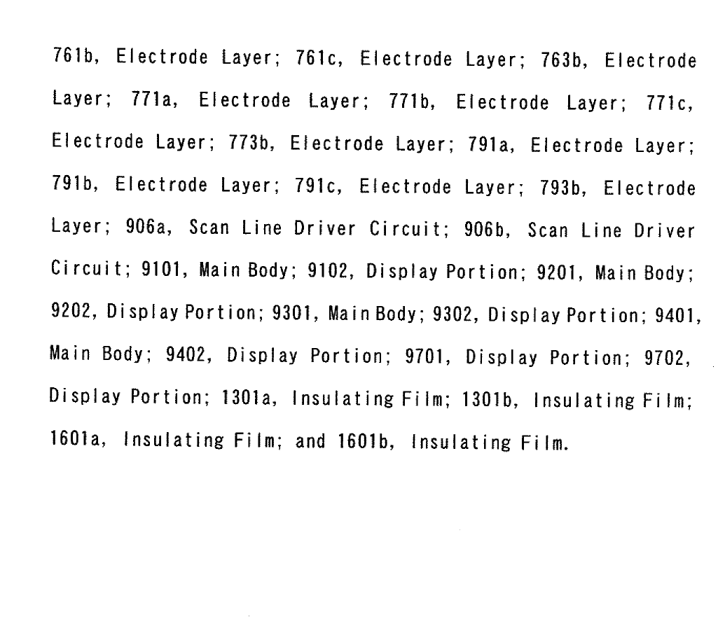

FIG. 27A is a top view of the light-emitting device, and FIG. 27B is a cross-sectional view taken along a line E-F in FIG. 27A. Although an EL layer 312, a second electrode layer 313, and an insulating layer 314 are not illustrated in FIG. 27A, they are provided as shown in FIG. 27B. The EL layer 312 has a light-emitting layer which includes an inorganic light-emitting material containing a mixed-valence compound.

First wirings 305a, 305c and 317 extending in a first direction and second wirings 302 extending in a second direction that is perpendicular to the first direction are provided in a matrix. The first wiring 305a are connected to a source electrode layer or drain electrode layer of a transistor 310a, the first wiring 305c are connected to a source electrode layer or drain electrode layer of a transistor 310b, the first wirings 317 are connected to the source electrode layer or the drain electrode layer of the transistor 310b′, and the second wirings 302 are connected to gate electrodes of the transistor 310b′. A first electrode layer 306a is connected to the source electrode layer or drain electrode layer of the transistor 310a, which is not connected to the first wiring, and a first electrode layer 306b is connected to the source electrode layer or the drain electrode layer of the transistor 310b, which is not connected to the first wiring. Light-emitting elements 315a and 315b are provided as a stacked structure of the first electrode layers 306a and 306b, the EL layer 312, and the second electrode layer 313. A partition wall (insulating layer) 307 is provided between adjacent light-emitting elements. The EL layer 312 and the second electrode layer 313 are stacked over the first electrode layers 306a and 306b and the partition wall (insulating layer) 307. An insulating layer 314 serving as a protective layer is provided over the second electrode layer 313. In addition, a thin film transistor is used for each of the transistors 310a and 310b (see FIG. 27B).

The light-emitting elements in FIG. 27B are provided over a substrate 300. Over the substrate 300, there are provided insulating layers 301a, 301b, 308, 309, and 311; a semiconductor layer 304a, a gate electrode layer 302a, and wirings 305a and 305b each serving as a source electrode layer or a drain electrode layer, which form the transistor 310a; and a semiconductor layer 304b, a gate electrode layer 302b, and wirings 305c and 305d each serving as a source electrode layer or a drain electrode layer, which form the transistor 310b. The EL layer 312 and the second electrode layer 313 are formed over the first electrode layers 306a and 306b and the partition wall (insulating layer) 307.

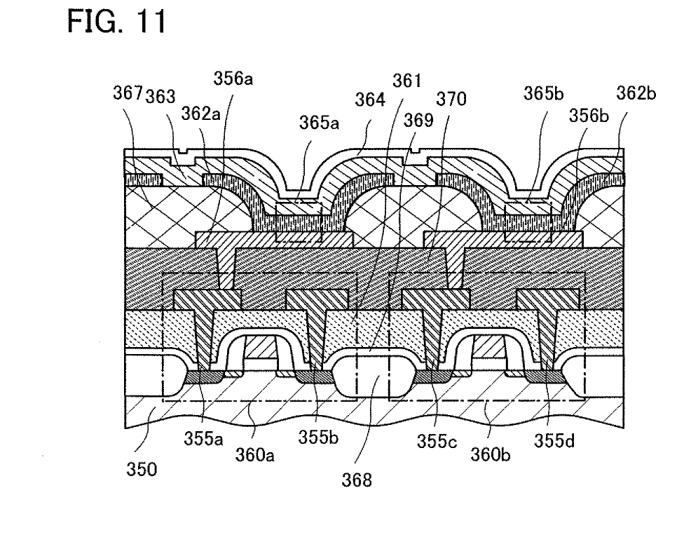

As shown in FIG. 11, light-emitting elements 365a and 365b may be connected to field effect transistors 360a and 360b, respectively, which are provided on a single-crystal semiconductor substrate 350. In this case, an insulating layer 370 is provided so as to cover source or drain electrode layers 355a to 355d of the field effect transistors 360a and 360b. Over the insulating layer 370, the light-emitting element 365a is formed of a first electrode layer 356a, a partition wall (insulating layer) 367, an EL layer 362a, and a second electrode layer 363; and the light-emitting element 365b is formed of a first electrode layer 356b, the partition wall (insulating layer) 367, an EL layer 362b, and the second electrode layer 363. The EL layer may selectively be provided with the use of a mask or the like only for each light-emitting element, like the EL layers 362a and 362b. The EL layers 362a and 362b each have a light-emitting layer which includes an inorganic light-emitting material containing a mixed-valence compound. Moreover, the light-emitting device shown in FIG. 11 also has an element isolating region 368 and insulating layers 369, 361, and 364. The EL layers 362a and 362b are formed over the first electrode layers 356a and 356b and the partition wall 367. Further, the second electrode layer 363 is formed over the EL layers 362a and 362b.

The EL layers 312, 362a, and 362b provided between electrode layers, which are manufactured using the present invention, each have a light-emitting layer which includes an inorganic light-emitting material containing a mixed-valence compound. The EL layers 312, 362a, and 362b may each have an insulating layer.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows: Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound of this embodiment mode using the present invention can be formed using the material described in Embodiment Mode 1.

Furthermore, a material in a mixed-valence state, which can be used in this embodiment mode, is specifically described. It is acceptable as long as an element that can be in a mixed-valence state is a metal element that can have a plurality of ion valences and has a large number of electrons; in particular, a transition metal or a rare earth metal is preferable. Examples of the metal element are typical elements belonging to Groups 13 to 15 of the periodic table, such as gallium (Ga), indium (In), thallium (Tl), tin (Sn), lead (Pb), and bismuth (Bi). Examples of the transition metal are elements belonging to Groups 4 to 12 of the periodic table, such as titanium (Ti), vanadium (V), chromium (Cr), manganese (Mn), iron (Fe), cobalt (Co), nickel (Ni), copper (Cu), niobium (Nb), molybdenum (Mo), ruthenium (Ru), rhodium (Rh), palladium (Pd), tungsten (W), rhenium (Re), iridium (Ir), platinum (Pt), and gold (Au). The rare earth metal refers to a lanthanoid or an actinoid of the periodic table, such as lantern (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), or ytterbium (Yb).

Examples of mixed-valence compound that can be used as a base material in a light-emitting material or that can be used in the present invention as a base material when the base material itself emits light are halides, oxides, sulfides, and the like.

Examples of oxides are LiWO₃, Pb₃O₄, CeVO₄, Sb₂O₄, Mn₃O₄, CuMn₂O₄, Co₃O₄, Zn_{X}Mn_{1-X}O, IrO₂, LaNiO₃, NiO, V₉O₅, MoO₃, WO₃, CaWO₄, YVO₄, Fe₃O₄, NiFe₂O₄, MnFe₂O₄, NaV₂O₅, Eu₃O₄, LiTi₂O₄, SrTiO₃, YBa₂Cu₃O₇, LiV₂O₅, and the like. Examples of sulfides are GaS, CuS, WS₂, Eu₃S₄, Yb₃S₄, TIS, and the like. Examples of halides, when a halogen element is represented by X, are InX₂, GaX₂, TlX₂, Ta₆Cl₁₅, Tl₄Cl₆, and the like. Examples of nitrides are InN, SnN, and the like and other examples are Eu₃As₄, Yb₃As₄, and the like.

The above-mentioned element can also be used when a mixed-valence element is used as an impurity element serving as a light-emission center. For example, a base material MX where a first impurity element (D) which forms a donor level and a second impurity element (A) which forms an acceptor level are added as impurity elements is expressed as MX:D,A. In this case, the first impurity element (D) which forms a donor level and the second impurity element (A) which forms an acceptor level contribute to light emission. A light-emitting material may contain one or more mixed-valence elements, and examples of light-emitting materials, which contain a mixed-valence element as a base material or which contain a mixed-valence element as an impurity element serving as a light-emission center, are as follows. It is needless to say that each of the base material and the impurity element serving as a light-emission center may be a mixed-valence compound (mixed-valence element). Examples of inorganic light-emitting materials that can be used in the present invention are as follows: ZnS:Cu; ZnO:Cu; Y₂O₃:Eu; SiAlON:Eu; MgGa₂O₄:Mn; ZnS:Fe; MgS:Eu; SrS:Sm; CaS:Eu; ZnS:Tm; ZnS:Tb; CaGa₂S₄:Ce; SrGa₂S₄:Ce; CaGa₂S₄:Ce; SrGa₂S₄:Ce; Zn₂SiO₄:Mn; YVO₄:Eu; ZnS:Mn; Zn_{X}Mg_{1-X}S:Cu, Cl; SrS:Cu; and the like. Some of oxides or sulfides are in a mixed-valence state when oxygen defect or sulfur defect are generated.

An inorganic light-emitting material that can be used in this embodiment mode includes a base material and an impurity element which serves as a light-emission center. By changing impurity elements to be included, various colors of light emission can be performed. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least one of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound. In an inorganic light-emitting material, an impurity element serving as a secondary activator may also be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When an impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state or may be generated in such a manner that a given valence state is excited and energy is transferred to another or the other valance state (or another or the other impurity element), and the valence state gaining the energy emits light.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly, chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

When the insulating layer 370 is formed and the light-emitting elements are the formed as shown in FIG. 11, the first electrode layers can be freely arranged. In other words, although the light-emitting elements 315a and 315b need to be provided in a region where the source electrode layer or drain electrode layer of each of the transistors 310a and 310b is not provided in the structure of FIG. 27B, the light-emitting elements 315a and 315b can be formed, for example, over the transistors 310a and 310b, respectively, in the above structure. Consequently, the light-emitting device can be more highly integrated.

The transistors 310a and 310b may have any structure as long as they can function as switching elements. Various semiconductors such as an amorphous semiconductor, a crystalline semiconductor, a polycrystalline semiconductor, and a microcrystal semiconductor can be used for a semiconductor layer, and an organic transistor may be formed using an organic compound. FIG. 27A shows an example in which a planar-type thin film transistor is provided over an insulating substrate; however, a transistor can also be a staggered type or an inverted staggered type.

When the light-emitting element in this embodiment mode has an EL layer provided with a light-emitting layer, which includes an inorganic light-emitting material containing a mixed-valence compound, between a pair of electrode layers, the electron transportability of the light-emitting layer is improved. Therefore, the light-emitting element can be driven at low voltage and can achieve a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 5

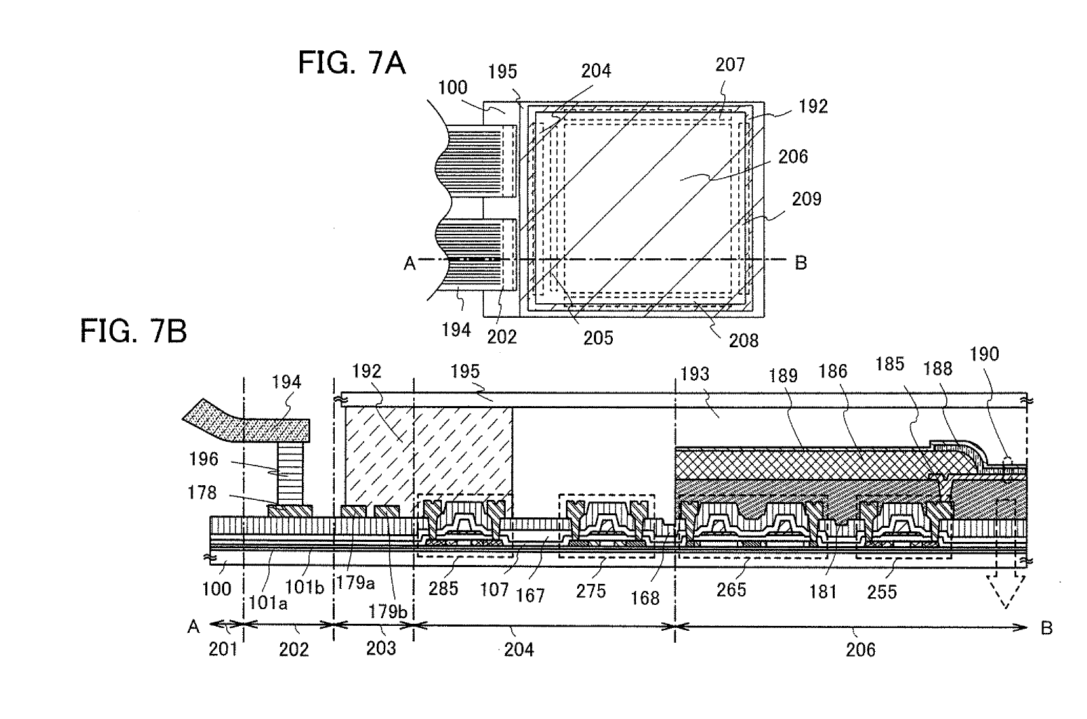

A method for manufacturing a light-emitting device of this embodiment mode will be described in detail with reference to FIGS. 7A and 7B, 8, 16A to 16C, and 17A and 17B.

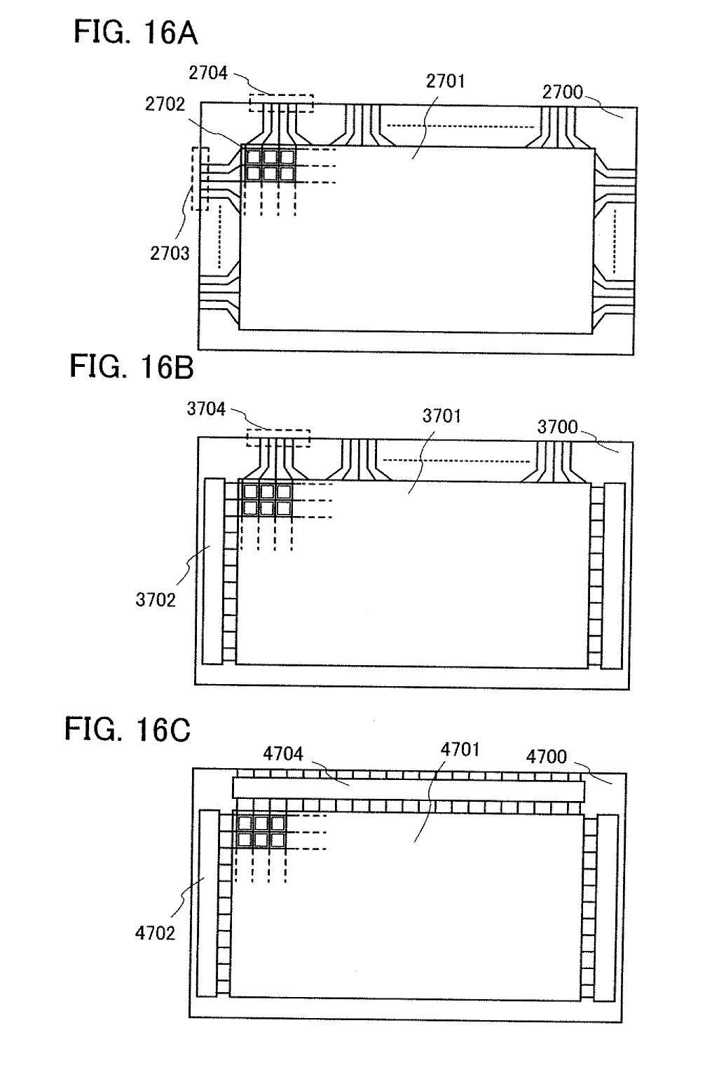

FIG. 16A is a top view showing a structure of a display panel according to the present invention, where a pixel portion 2701 in which pixels 2702 are arranged in matrix, a scan line side input terminal 2703, and a signal line side input terminal 2704 are formed over a substrate 2700 having an insulating surface. The number of pixels may be determined in accordance with various standards. In the case of XGA full color display using RGB, the number of pixels may be 1024×768×3 (RGB). In the case of UXGA full color display using ROB, the number of pixels may be 1600×1200×3 (RGB), and in the case of full-spec high-definition full color display using RGB, the number of pixels may be 1920×1080×3 (RGB).

The pixels 2702 are arranged in matrix at intersections of scan lines extending from the scan line side input terminal 2703 and signal lines extending from the signal line side input terminal 2704. Each of the pixels 2702 is provided with a switching element and a pixel electrode layer connected to the switching element. A typical example of the switching element is a TFT. The gate electrode layer side of the TFT is connected to a scan line, and a source or drain side of the TFT is connected to a signal line, which enables each pixel to be independently controlled by signals that are input from an external portion.

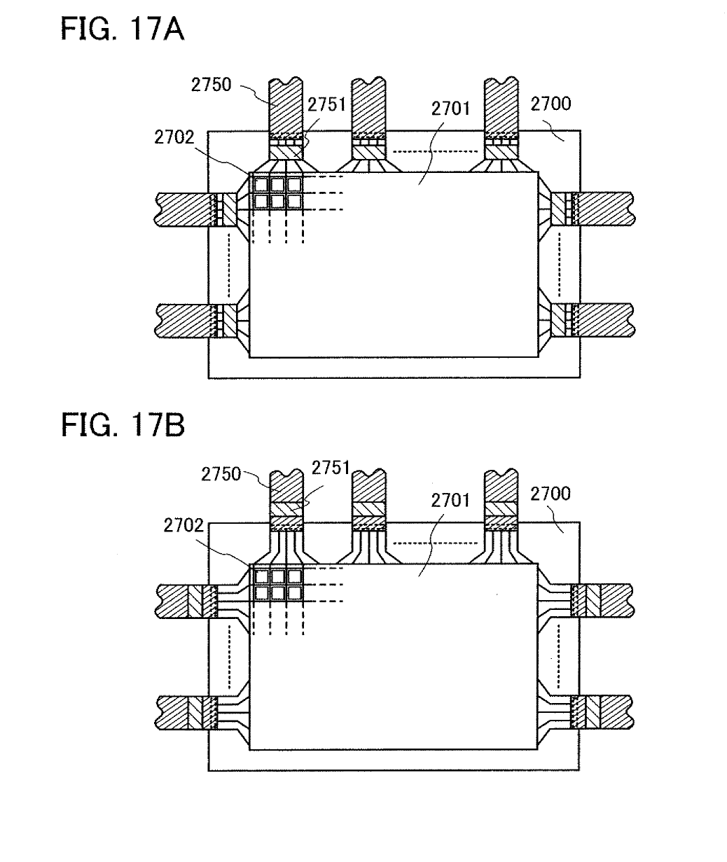

FIG. 16A shows a structure of a display panel in which signals to be input to the scan lines and the signal lines are controlled by an external driver circuit. Alternatively, a driver IC 2751 may be mounted on the substrate 2700 by a COG (Chip on Glass) method as shown in FIG. 17A. As another mounting mode, a TAB (Tape Automated Bonding) method may also be used as shown in FIG. 17B. The driver IC may be formed on a single-crystal semiconductor substrate or may be formed with a TFT over a glass substrate. In each of FIGS. 17A and 17B, the driver IC 2751 is connected to a flexible printed circuit (FPC) 2750.

When a TFT provided in a pixel is formed from a crystalline semiconductor, a scan line side driver circuit 3702 can be formed over a substrate 3700 as shown in FIG. 16B. In FIG. 16B, a pixel portion 3701 is controlled by an external driver circuit connected to a signal line side input terminal 3704 as in FIG. 16A. When a TFT in a pixel is formed from a polycrystalline (microcrystalline) semiconductor, a single-crystal semiconductor, or the like having high mobility, a pixel portion 4701, a scan line side driver circuit 4702, and a signal line side driver circuit 4704 can all be formed over a substrate 4700 as shown in FIG. 16C.

As a base film over a substrate 100 having an insulating surface, a base film 101a is formed using a silicon nitride oxide film with a thickness of 10 nm to 200 nm (preferably, 50 nm to 150 nm) and a base film 101b is stacked thereover using a silicon oxynitride film with a thickness of 50 nm to 200 nm (preferably, 100 nm to 150 nm) by a sputtering method, a physical vapor deposition (PVD) method, a chemical vapor deposition (CVD) method such as a low pressure CVD (LPCVD) method or a plasma CVD method, or the like. Alternatively, it is also possible to use an acrylic acid, a methacrylic acid, or a derivative thereof; a heat-resistant high-molecular compound such as polyimide, aromatic polyamide, or polybenzimidazole; or a siloxane resin. Further, the following resin material can be used: a vinyl resin such as polyvinyl alcohol or polyvinyl butyral; an epoxy rein; a phenol resin; a novolac resin; an acrylic rein; a melamine resin; a urethane resin; and the like. In addition, it is also possible to use an organic material such as benzocyclobutene, parylene, fluorinated arylene ether, or polyimide or the like. Further, an oxazole resin such as photo-curing polybenzoxazole can also be used.

Further, a droplet discharging method, a printing method (a method by which a pattern can be formed, such as screen printing or offset printing), a coating method such as a spin coating method, a dipping method, a dispenser method, or the like can also be used. In this embodiment mode, the base films 101a and 101b are formed by a plasma CVD method. As the substrate 100, a glass substrate, a quartz substrate, a silicon substrate, a metal substrate, or a stainless steel substrate having an insulating film formed on its surface may be used. Alternatively, a plastic substrate having heat resistance to the processing temperature in this embodiment mode, or a flexible substrate such as a film may also be used. As a plastic substrate, a substrate made of polyethylene terephthalate (PET), polyethylene naphthalate (PEN), or polyethersulfone (PES) can be used. As a flexible substrate, a synthetic resin such as acrylic can be used. Because a light-emitting device manufactured in this embodiment mode has a structure in which light is extracted from the light-emitting element through the substrate 100, the substrate 100 needs to have a light-transmitting property.

For the base film, silicon oxide, silicon nitride, silicon oxynitride, silicon nitride oxide, or the like can be used, and either a single layer structure or a stacked-layer structure including two or three layers can be employed.

Next, a semiconductor film is formed over the base film. The semiconductor film may be formed with a thickness of 25 nm to 200 nm (preferably, 30 nm to 150 nm) by various methods (such as a sputtering method, an LPCVD method, and a plasma CVD method). In this embodiment mode, it is preferable to use a crystalline semiconductor film which is obtained by crystallizing an amorphous semiconductor film by laser irradiation.

The semiconductor film can be formed using a material such as an amorphous semiconductor (hereinafter also referred to as “AS”) formed by a vapor deposition method using a semiconductor material gas typified by silane or germane or by a sputtering method, a polycrystalline semiconductor formed by crystallizing an amorphous semiconductor using light energy or thermal energy, or a semi-amorphous semiconductor (also referred to as a microcrystalline semiconductor and hereinafter also referred to as “SAS”).

A SAS is a semiconductor having an intermediate structure between amorphous and crystalline (including single-crystal and polycrystalline) structures and a third state which is stable in terms of free energy. Moreover, a SAS includes a crystalline region with a short-range order and lattice distortion. A SAS is formed by glow discharge decomposition (plasma CVD) of a gas containing silicon. As the gas containing silicon, SiH₄ can be used, and alternatively, Si₂H₆, SiH₂Cl₂, SiHCl₃, SiCl₄, SiF₄, and the like can be used. Further, a mixture of F₂ and GeF₄ may be used. The gas containing silicon may be diluted with H₂, or with H₂ and one or more kinds of rare gas elements of He, Ar, Kr, and Ne. Further, when a rare gas element such as helium, argon, krypton, or neon is contained to further increase the lattice distortion, thereby enhancing stability and obtaining a favorable SAS. Further, as the semiconductor film, a SAS layer formed by using a hydrogen-based gas may be stacked over a SAS layer formed by using a fluorine-based gas.

A typical example of an amorphous semiconductor is hydrogenated amorphous silicon or the like and a typical example of a crystalline semiconductor is polysilicon or the like. Polysilicon (polycrystalline silicon) includes so-called high-temperature polysilicon formed using, as a main material, polysilicon which is formed at a processing temperature of 800° C. or higher, so-called low-temperature polysilicon formed using, as a main material, polysilicon which is formed at a processing temperature of 600° C. or lower, polysilicon which is obtained by crystallizing amorphous silicon with the use of an element which promotes crystallization, and the like. Of course, as described above, a semi-amorphous semiconductor or a semiconductor which includes a crystalline phase in a portion thereof can also be used.

When a crystalline semiconductor film is used as the semiconductor film, the crystalline semiconductor film may be formed by a known method (such as a laser crystallization method, a thermal crystallization method, or a thermal crystallization method using an element which promotes crystallization, such as nickel). Further, a microcrystalline semiconductor that is a SAS may be crystallized by laser irradiation to enhance crystallinity. In a case where an element which promotes crystallization is not used, before the amorphous silicon film is irradiated with a laser beam, the amorphous silicon film is heated at 500° C. for one hour in a nitrogen atmosphere to release hydrogen from the amorphous silicon film to a concentration of 1×10²⁰ atoms/cm³ or less. This is because, if the amorphous silicon film contains much hydrogen, the amorphous silicon film may be broken by laser irradiation. Heat treatment for crystallization may be performed by using a heating furnace, laser irradiation, irradiation with light emitted from a lamp (also called lamp annealing), or the like. As a heating method, an RTA method such as a gas rapid thermal anneal (GRTA) method or a lamp rapid thermal anneal (LRTA) method may be used. A GRTA method is a method for performing heat treatment by using a high-temperature gas, and an LRTA method is a method for performing heat treatment by light emitted from a lamp.

In a crystallization step in which an amorphous semiconductor film is crystallized to form a crystalline semiconductor film, an element which promotes crystallization (also referred to as a catalytic element or a metal element) may be added to the amorphous semiconductor film, and crystallization may be performed by heat treatment (at 550° C. to 750° C. for 3 minutes to 24 hours). As the element which promotes crystallization, one or more of iron (Fe), nickel (Ni), cobalt (Co), ruthenium (Ru), rhodium (Rh), palladium (Pd), osmium (Os), iridium (Ir), platinum (Pt), copper (Cu), and gold (Au) can be used.

A method for introducing a metal element into the amorphous semiconductor film is not particularly limited as long as it is a method for allowing the metal element to be on the surface of or inside the amorphous semiconductor film. For example, a sputtering method, a CVD method, a plasma treatment method (including a plasma CVD method), an adsorption method, or a method for applying a solution of metal salt can be used. Among them, a method using a solution is simple and advantageous in that the concentration of the metal element can be easily controlled. At this time, it is desirable to form an oxide film by UV light irradiation in an oxygen atmosphere, a thermal oxidation method, treatment with ozone water containing hydroxyl radical or hydrogen peroxide, or the like in order to improve wettability of the surface of the amorphous semiconductor film so that an aqueous solution is spread over the entire surface of the amorphous semiconductor film.

In order to remove or reduce the element which promotes crystallization from the crystalline semiconductor film, a semiconductor film containing an impurity element is formed to be in contact with the crystalline semiconductor film and is made to function as a gettering sink. As the impurity element, an impurity element imparting n-type conductivity, an impurity element imparting p-type conductivity, a rare gas element, or the like can be used. For example, one or more of phosphorus (P), nitrogen (N), arsenic (As), antimony (Sb), bismuth (Bi), boron (B), helium (He), neon (Ne), argon (Ar), krypton (Kr), and xenon (Xe) can be used. A semiconductor film containing a rare gas element is formed to be in contact with the crystalline semiconductor film containing the element which promotes crystallization, and heat treatment (at 550° C. to 750° C. for 3 minutes to 24 hours) is performed. The element which promotes crystallization contained in the crystalline semiconductor film moves into the semiconductor film containing a rare gas element, and thus, the element which promotes crystallization contained in the crystalline semiconductor film is removed or reduced. After that, the semiconductor film containing a rare gas element that has served as a gettering sink is removed.

By relatively scanning a semiconductor film with a laser, laser irradiation can be performed. In laser irradiation, a marker can also be formed in order to overlap beams with high accuracy or control a start position or an end position of laser irradiation. The marker may be formed over the substrate at the same time as the amorphous semiconductor film.

In a case of employing laser irradiation, a continuous-wave laser beam (CW laser beam) or a pulsed laser beam can be used. An applicable laser beam is a beam emitted from one or more kinds of the following lasers: a gas laser such as an Ar laser, a Kr laser, or an excimer laser; a laser using, as a medium, single-crystal YAG, YVO₄, forsterite (Mg₂SiO₄), YAlO₃, or GdVO₄, or polycrystalline (ceramic) YAG, Y₂O₃, YVO₄, YAlO₃, or GdVO₄, to which one or more of Nd, Yb, Cr, Ti, Ho, Er, Tm, and Ta is added as a dopant; a glass laser; a ruby laser; an alexandrite laser; a Ti:sapphire laser; a copper vapor laser; and a gold vapor laser. A crystal having a large grain size can be obtained by irradiation with the fundamental wave of the above laser beam or the second harmonic to the fourth harmonic of the fundamental wave thereof. For example, the second harmonic (532 nm) or the third harmonic (355 nm) of a Nd:YVO₄ laser (the fundamental wave: 1064 nm) can be used. This laser can emit either a CW laser beam or a pulsed laser beam. When the laser emits a CW laser beam, a power density of the laser needs to be about 0.01 MW/cm² to 100 MW/cm² (preferably, 0.1 MW/cm² to 10 MW/cm²). A scanning rate is set to about 10 cm/sec to 2000 cm/sec for irradiation.

Note that the laser using, as a medium, single-crystal YAG, YVO₄, forsterite (Mg₂SiO₄), YAlO₃, or GdVO₄, or polycrystalline (ceramic) YAG, Y₂O₃, YVO₄, YAlO₃, or GdVO₄, to which one or more of Nd, Yb, Cr, Ti, Ho, Er, Tm, and Ta is added as a dopant; an Ar ion laser; or a Ti:sapphire laser can emit a CW beam. Alternatively, it can emit a pulsed beam at a repetition rate of 10 MHz or more by performing Q-switching operation, modelocking, or the like. When a laser beam is pulsed at a repetition rate of 10 MHz or more, the semiconductor layer is irradiated with a pulsed laser beam after being melted by a preceding laser beam and before being solidified. Therefore, unlike a case of using a pulsed laser having a low repetition rate, the interface between the solid phase and the liquid phase can be moved continuously in the semiconductor film, so that crystal grains grown continuously in the scanning direction can be obtained.

When ceramic (polycrystal) is used as a medium, the medium can be formed into a desired shape in a short time at low cost. In the case of using a single crystal, a columnar medium having a diameter of several millimeters and a length of several tens of millimeters is generally used. However, in the case of using ceramic, a larger medium can be formed.

The concentration of a dopant such as Nd or Yb in a medium, which directly contributes to light emission, cannot be changed largely either in a single crystal or in a polycrystal. Therefore, there is a limitation on improvement in laser output by increasing the concentration. However, in the case of using ceramic, the size of the medium can be significantly increased compared with the case of using a single crystal, and thus, a significant improvement in output can be achieved.

Furthermore, in the case of using ceramic, a medium having a parallelepiped shape or a rectangular solid shape can be easily formed. When a medium having such a shape is used and emitted light is made to propagate inside the medium in zigzag, an emitted light path can be extended. Therefore, the light is amplified largely and can be emitted with high output. In addition, since a laser beam emitted from a medium having such a shape has a quadrangular shape in cross-section at the time of emission, it has an advantage over a circular beam in being shaped into a linear beam. By shaping the laser beam emitted as described above using an optical system, a linear beam having a length of 1 mm or less on a shorter side and a length of several millimeters to several meters on a longer side can be easily obtained. Further, by uniformly irradiating the medium with excited light, the linear beam has a uniform energy distribution in a long-side direction. Moreover, the semiconductor film is preferably irradiated with the laser beam at an incident angle θ (0°<θ<90°) because laser interference can be prevented.

By irradiating the semiconductor film with this linear beam, the entire surface of the semiconductor film can be annealed more uniformly. When uniform annealing is needed to both ends of the linear beam, a device of providing slits at the both ends so as to block a portion of light where energy is attenuated, or the like is necessary.

When the linear beam with uniform intensity, which is obtained as described above, is used for annealing the semiconductor film and a light-emitting device is manufactured using this semiconductor film, the light-emitting device has favorable and uniform characteristics.

The laser light irradiation may be performed in an inert gas atmosphere such as in a rare gas or nitrogen. This can suppress surface roughness of the semiconductor film due to laser light irradiation and variation of threshold value which is caused by variation of interface state density.

The amorphous semiconductor film may be crystallized by a combination of heat treatment and laser light irradiation or by several times of heat treatment or laser light irradiation alone.

In this embodiment mode, the amorphous semiconductor film is formed over the base film 101b, and the amorphous semiconductor film is crystallized, thereby forming a crystalline semiconductor film.

After removing the oxide film which has been formed over the amorphous semiconductor film, an oxide film is formed with a thickness of 1 nm to 5 nm by UV light irradiation in an oxygen atmosphere, a thermal oxidization method, treatment with ozone water containing hydroxyl radical or a hydrogen peroxide solution, or the like. In this embodiment mode, Ni is used as the element which promotes crystallization. An aqueous solution containing Ni acetate of 10 ppm is applied by a spin coating method.

In this embodiment mode, after heat treatment is performed by an RTA method at 750° C. for three minutes, an oxide film which is formed on the semiconductor film is removed and laser irradiation is performed. The amorphous semiconductor film is crystallized by this crystallization treatment to be a crystalline semiconductor film.

In the case of performing crystallization using a metal element, gettering is performed in order to reduce or remove the metal element. In this embodiment mode, the metal element is captured using an amorphous semiconductor film as a gettering sink. First, an oxide film is formed on the crystalline semiconductor film by UV light irradiation in an oxygen atmosphere, thermal oxidation, treatment with ozone water containing hydroxyl radical or hydrogen peroxide, or the like. The oxide film is preferably increased in thickness by heat treatment. Next, an amorphous semiconductor film is formed with a thickness of 50 nm by a plasma CVD method (under conditions in this embodiment mode: 350 W, 35 Pa, deposition gases of SiH₄ (at a flow rate of 5 sccm) and Ar (at a flow rate of 1000 sccm)).

After that, heat treatment is performed by an RTA method at 744° C. for three minutes, thereby reducing or removing the metal element. The heat treatment may be performed in a nitrogen atmosphere. Then, the amorphous semiconductor film serving as a gettering sink and the oxide film formed on the amorphous semiconductor film are removed by hydrofluoric acid or the like; accordingly, a crystalline semiconductor film where the metal element has been reduced or removed can be obtained. In this embodiment mode, the amorphous semiconductor film serving as a gettering sink is removed using tetramethyl ammonium hydroxide (TMAH).

The semiconductor film obtained in this manner may be doped with a slight amount of impurity element (boron or phosphorus) in order to control the threshold voltage of a thin film transistor. Such doping with the impurity element may be performed before the crystallization step of the amorphous semiconductor film. When the amorphous semiconductor film is doped with an impurity element and then subjected to heat treatment for crystallization, activation of the impurity element can also be performed. In addition, defects caused in doping and the like can be repaired.

Next, the crystalline semiconductor film is processed by etching into a desired shape, whereby a semiconductor layer is formed.

For the etching processing, either plasma etching (dry etching) or wet etching may be employed. In a case of processing a large substrate, plasma etching is suitable. As an etching gas, a fluorine-based gas such as CF₄ or NF₃ or a chlorine-based gas such as Cl₂ or BCl₃ is used, to which an inert gas such as He or Ar may be appropriately added. When etching processing using atmospheric discharge is employed, localized discharge processing is also possible, and a mask layer does not need to be formed over the entire surface of the substrate.

In the present invention, a conductive layer for forming a wiring layer or an electrode layer, a mask layer for forming a predetermined pattern, or the like may also be formed by a method by which a pattern can be selectively formed, such as a droplet discharging method. By a droplet discharging (jetting) method (also called an ink jet method depending on its system), a predetermined pattern (such as a conductive layer or an insulating layer) can be formed by selectively discharging (jetting) droplets of a composition which is prepared for a particular purpose. At this time, treatment for controlling wettability or adhesion may be performed to a formation region. Alternatively, a method by which a pattern can be transferred or drawn, for example, a printing method (a method by which a pattern can be formed, such as screen printing or offset printing), a dispenser method, or the like can be used.

In this embodiment mode, for a mask, a resin material such as an epoxy resin, an acrylic resin, a phenol resin, a novolac resin, a melamine resin, or a urethane resin is used. Alternatively, an organic material such as benzocyclobutene, parylene, fluorinated arylene ether, or polyimide having a light transmitting property, a compound material formed by polymerization of siloxane-based polymers or the like, and the like can be used. Further alternatively, a commercially-available resist material containing a photosensitizer such as a positive-type resist or a negative-type resist may also be used. Even when a droplet discharging method is used with any material, the surface tension and the viscosity of the material are appropriately adjusted by adjusting the concentration of a solvent or by adding a surfactant or the like.

A gate insulating layer 107 is formed to cover the semiconductor layer. The gate insulating layer is formed using an insulating film containing silicon with a thickness of 10 nm to 150 nm by a plasma CVD method, a sputtering method, or the like. The gate insulating layer may be formed using a known material such as an oxide material or a nitride material of silicon, typified by silicon nitride, silicon oxide, silicon oxynitride, or silicon nitride oxide, and may be a stacked layer or a single layer. The insulating layer may be a stacked layer of three layers of a silicon nitride film, a silicon oxide film, and a silicon nitride film, or a single layer or a stacked layer of two layers of a silicon oxynitride film.

Next, a gate electrode layer is formed over the gate insulating layer 107. The gate electrode layer can be formed by a sputtering method, an evaporation method, a CVD method, or the like. The gate electrode layer may be formed using an element selected from tantalum (Ta), tungsten (W), titanium (Ti), molybdenum (Mo), aluminum (Al), copper (Cu), chromium (Cr), or neodymium (Nd), or an alloy material or a compound material containing the element as its main component. Further, as the gate electrode layer, a semiconductor film typified by a polycrystalline silicon film doped with an impurity element such as phosphorus, or an AgPdCu alloy may be used. In addition, the gate electrode layer may be a single layer or a stacked layer.

In this embodiment mode, the gate electrode layer is formed into a tapered shape; however, the present invention is not limited thereto. The gate electrode layer may have a stacked-layer structure where only one layer has a tapered shape while the other has a perpendicular side surface by anisotropic etching. The stacked gate electrode layers may have different taper angles as in this embodiment mode or may have the same taper angle. With the tapered shape, coverage by a film that is stacked thereover is improved and defects are reduced, whereby reliability is increased.

The gate insulating layer 107 may be etched to some extent and reduced in thickness (so-called film decrease) by the etching step for forming the gate electrode layer.

An impurity element is added to the semiconductor layer to form an impurity region. The impurity region can be formed as a high-concentration impurity region and a low-concentration impurity region through the control of the concentration of the impurity element. The structure of a thin film transistor having a low-concentration impurity region is referred to as a light doped drain (LDD) structure. In addition, the low-concentration impurity region can be formed so as to overlap with the gate electrode layer. Such a structure of a thin film transistor is referred to as a gate overlapped LDD (GOLD) structure. The polarity of the thin film transistor is made to be n-type through addition of phosphorus (P) or the like to an impurity region thereof. In a case where a p-type thin film transistor is formed, boron (B) or the like may be added.

In this embodiment mode, a region of the impurity region, which overlaps with the gate electrode layer with the gate insulating layer interposed therebetween, is referred to as a Lov region. A region of the impurity region, which does not overlap with the gate electrode layer with the gate insulating layer interposed therebetween, is referred to as a Loff region. In FIG. 7B, the impurity regions are indicated by hatching and a blank space. This does not mean that the blank space is not doped with an impurity element, but makes it easy to understand that the concentration distribution of the impurity element in these regions reflects the mask or the doping condition. It is to be noted that this applies to other drawings of this specification.

In order to activate the impurity element, heat treatment, strong light irradiation, or laser beam irradiation may be performed. At the same time as the activation, plasma damage to the gate insulating layer and plasma damage to the interface between the gate insulating layer and the semiconductor layer can be recovered.

Next, a first interlayer insulating layer is formed to cover the gate electrode layer and the gate insulating layer. In this embodiment mode, the first interlayer insulating layer has a stacked layer structure of insulating films 167 and 168. The insulating films 167 and 168 can be formed using a silicon nitride film, a silicon nitride oxide film, a silicon oxynitride film, a silicon oxide film, or the like by a sputtering method or a plasma CVD method. Alternatively, it may be a single layer of another insulating film containing silicon or may have a stacked-layer structure of three or more layers of other insulating films containing silicon.

Furthermore, heat treatment is performed at 300° C. to 550° C. for 1 to 12 hours in a nitrogen atmosphere, and the semiconductor layer is hydrogenated. Preferably, this heat treatment is performed at 400° C. to 500° C. Through this step, dangling bonds in the semiconductor layer are terminated by hydrogen contained in the insulating film 167 that is an interlayer insulating layer. In this embodiment mode, heat treatment is performed at 410° C.

The insulating films 167 and 168 can also be formed using a material of aluminum nitride (AlN), aluminum oxynitride (AlON), aluminum nitride oxide containing more nitrogen than oxygen (AlNO), aluminum oxide, diamond-like carbon (DLC), nitrogen-containing carbon (CN), polysilazane, or another substance containing an inorganic insulating material. A material containing siloxane may also be used. Further, an organic insulating material such as polyimide, acrylic, polyamide, polyimide amide, resist, or benzocyclobutene may also be used. In addition, an oxazole resin can be used, and for example, photo-curable type polybenzoxazole or the like can be used.

Next, contact holes (openings), which each reach the semiconductor layer, are formed in the insulating films 167 and 168 and the gate insulating layer 107 with the use of a mask formed of a resist. A conductive film is formed so as to cover the openings, and the conductive film is etched, whereby a source electrode layer and a drain electrode layer are formed, which are electrically connected to part of a source region and a drain region, respectively. In order to form the source electrode layer and the drain electrode layer, a conductive film is formed by a PVD method, a CVD method, an evaporation method, or the like, and the conductive film is etched into a desired shape. Alternatively, a conductive layer can be selectively formed in a predetermined place by a droplet discharging method, a printing method, a dispenser method, an electroplating method, or the like. A reflow method or a damascene method may also be used. The source electrode layer and the drain electrode layer are formed using a metal such as Ag, Au, Cu, Ni, Pt, Pd, Ir, Rh, W, Al, Ta, Mo, Cd, Zn, Fe, Ti, Si, Ge, Zr, or Ba, or an alloy or a nitride thereof. Alternatively, a stacked layer structure of these materials may be used.

Through the above steps, an active-matrix substrate can be manufactured, in which a p-channel thin film transistor 285 having a p-type impurity region in a Lov region and an n-channel thin film transistor 275 having an n-channel impurity region in a Lov region are provided in a peripheral driver circuit region 204; and a multi-channel type n-channel thin film transistor 265 having an n-type impurity region in a Loff region and a p-channel thin film transistor 245 having a p-type impurity region in a Lov region are provided in a pixel region 206.

The structure of the thin film transistor is not limited to this embodiment mode, and a single-gate structure in which one channel formation region is formed, a double-gate structure in which two channel formation regions are formed, or a triple-gate structure in which three channel formation regions are formed may be employed. Further, the thin film transistor in the peripheral driver circuit region may also employ a single-gate structure, a double-gate structure, or a triple-gate structure.

Next, an insulating film 181 is formed as a second interlayer insulating layer. In FIGS. 7A and 7B, a separation region 201 for separation by scribing, an external terminal connection region 202 to which an FPC is attached, a wiring region 203 that is a lead wiring region for the peripheral portion, the peripheral driver circuit region 204, and the pixel region 206 are provided. Wirings 179a and 179b are provided in the wiring region 203, and a terminal electrode layer 178 connected to an external terminal is provided in the external terminal connection region 202.

The insulating film 181 can be formed using a material selected from silicon oxide, silicon nitride, silicon oxynitride, silicon nitride oxide, aluminum nitride (AlN), aluminum oxide containing nitrogen (also referred to as aluminum oxynitride) (AlON), aluminum nitride containing oxygen (also referred to as aluminum nitride oxide) (AlNO), aluminum oxide, diamond-like carbon (DLC), nitrogen-containing carbon (CN), phosphosilicate glass (PSG), borophosphosilicate glass (BPSG), alumina, and other substances containing an inorganic insulating material. Alternatively, a siloxane resin may be used. Further, a photosensitive or non-photosensitive organic insulating material such as polyimide, acrylic, polyamide, polyimide amide, resist, benzocyclobutene, polysilazane, or a low-dielectric constant material (Low-k material) can also be used. Still alternatively, an oxazole resin can be used, and for example, photo-curable type polybenzoxazole or the like can be used. An interlayer insulating layer provided for planarization is required to have high heat resistance, a high insulating property, and a high level of planarity. Thus, the insulating film 181 is preferably formed by a coating method typified by a spin coating method.

The insulating film 181 can be formed by a dipping method, spray coating, a doctor knife, a roll coater, a curtain coater, a knife coater, a CVD method, an evaporation method, or the like. The insulating film 181 may also be formed by a droplet discharging method. In the case of a droplet discharging method, a material solution can be saved. In addition, a method by which a pattern can be transferred or drawn, like a droplet discharging method, for example, a printing method (a method by which a pattern cam be formed, such as screen printing or offset printing), a dispenser method, or the like can also be used.

A minute opening, that is, a contact hole is formed in the insulating film 181 in the pixel region 206.

Next, a first electrode layer 185 (also referred to as a pixel electrode layer) is formed so as to be in contact with the source electrode layer or the drain electrode layer. The first electrode layer 185 functions as an anode or a cathode and may be formed using an element such as Ti, Ni, W, Cr, Pt, Zn, Sn, In, or Mo; an alloy material or a compound material containing the above element as its main component such as TiN, TiSi_{X}N_{Y}, WSi_{X}, WN_{X}, WSi_{X}N_{Y}, or NbN; or a stacked film thereof with a total thickness of 100 nm to 800 nm.

In this embodiment mode, the first electrode layer 185 has a light-transmitting property because light from the light-emitting element is extracted from the first electrode layer 185 side. The first electrode layer 185 is formed using a transparent conductive film which is etched into a desired shape.

In the present invention, the first electrode layer 185 that is a light-transmitting electrode layer may be specifically formed using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. Of course, indium tin oxide (ITO), indium zinc oxide (IZO), indium tin oxide to which silicon oxide is added (ITSO), or the like can also be used.

In addition, even in the case of using a non-light-transmitting material such as a metal film, when the thickness is made to be thin (preferably, about 5 nm to 30 nm) so as to be able to transmit light, light can be emitted through the first electrode layer 185. As a metal thin film that can be used for the first electrode layer 185, a conductive film formed of titanium, tungsten, nickel, gold, platinum, silver, aluminum, magnesium, calcium, lithium, or an alloy thereof, or the like can be used.

The first electrode layer 185 can be formed by an evaporation method, a sputtering method, a CVD method, a printing method, a dispenser method, a droplet discharging method, or the like. In this embodiment mode, the first electrode layer 185 is formed by a sputtering method using indium zinc oxide containing tungsten oxide. The first electrode layer 185 is preferably formed with a total thickness of 100 nm to 800 nm.

The first electrode layer 185 may be cleaned and polished by a CMP method or with the use of a polyvinylalcohol-based porous material so that the surface thereof is planarized. In addition, after polishing by a CMP method, ultraviolet light irradiation, oxygen plasma treatment, or the like may be performed to the surface of the first electrode layer 185.

After the first electrode layer 185 is formed, heat treatment may be performed. By the heat treatment, moisture contained in the first electrode layer 185 is released. Accordingly, degasification or the like is not caused in the first electrode layer 185. Thus, even when a light-emitting material that is easily deteriorated by moisture is formed over the first electrode layer, the light-emitting material is not deteriorated; therefore, a highly-reliable light-emitting device can be manufactured.

Next, an insulating layer 186 (also referred to as a partition wall or a barrier) is formed to cover the edge of the first electrode layer 185 and the source electrode layer and the drain electrode layer.

The insulating layer 186 can be formed using silicon oxide, silicon nitride, silicon oxynitride, silicon nitride oxide, or the like, and may have a single-layer structure or a stacked-layer structure including two or three layers. Alternatively, the insulating layer 186 can be formed using a material containing aluminum nitride, aluminum oxynitride containing more oxygen than nitrogen, aluminum nitride oxide containing more nitrogen than oxygen, aluminum oxide, diamond-like carbon (DLC), nitrogen-containing carbon, polysilazane, or another inorganic insulating material can be used. A material containing siloxane may also be used. Further, a photosensitive or non-photosensitive organic insulating material such as polyimide, acrylic, polyamide, polyimide amide, resist, benzocyclobutene, or polysilazane, can also be used. In addition, an oxazole resin can be used, and for example, photo-curable type polybenzoxazole or the like can be used.

The insulating layer 186 can be formed by a sputtering method, a physical vapor deposition (PVD) method, a chemical vapor deposition (CVD) method such as a low-pressure CVD (LPCVD) method or a plasma CVD method, a droplet discharging method by which a pattern can be selectively formed, a printing method by which a pattern can be transferred or drawn (a method by which a pattern can be formed, such as screen printing or offset printing), a dispenser method, a coating method such as a spin coating method, a dipping method, or the like.

For etching processing for processing into a desired shape, either plasma etching (dry etching) or wet etching may be employed. In the case where a large substrate is processed, plasma etching is suitable. As an etching gas, a fluorine-based gas such as CF₄ or NF₃, or a chlorine-based gas such as Cl₂ or BCl₃ is used, to which an inert gas such as He or Ar may be appropriately added. When an etching process using atmospheric discharge is employed, a localized discharge process is also possible, and a mask layer does not need to be formed over the entire surface of the substrate.

In a connection region 205 shown in FIG. 7A, a wiring layer formed of the same material and through the same steps as those of a second electrode layer is electrically connected to a wiring layer formed of the same material and through the same steps as those of the gate electrode layer.

An EL layer 188 is formed over the first electrode layer 185. The EL layer 188 has a light-emitting layer which includes an inorganic light-emitting material containing a mixed-valence compound. Although only one pixel is shown in FIG. 7B, EL layers corresponding to R (red), G (green), and B (blue) are formed in this embodiment mode. The EL layer 188 may be manufactured as described in Embodiment Mode 1.

The EL layer 188 provided between electrode layers, which is manufactured using the present invention, has a light-emitting layer which includes an inorganic light-emitting material containing a mixed-valence compound. In addition, the EL layer 188 may have an insulating layer as described in Embodiment Mode 1 and as shown in FIGS. 2A to 3C. The light-emitting element of this embodiment mode using the present invention can be specifically formed using the structure, material, and method that are described in Embodiment Mode 1.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows: Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound of this embodiment mode using the present invention can be formed using the material described in Embodiment Mode 1.

An inorganic light-emitting material that can be used in this embodiment mode includes a base material and an impurity element which serves as a light-emission center. By changing impurity elements to be included, various colors of light emission can be performed. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least on of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound. In an inorganic light-emitting material, an impurity element serving as a secondary activator may also be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When an impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state or may be generated in such a manner that a given valence state is excited and energy is transferred to another or the other valance state (or another or the other impurity element), and the valence state gaining the energy emits light.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly, chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

Next, a second electrode layer 189 formed of a conductive film is provided over the EL layer 188. The second electrode layer 189 may be formed using Al, Ag, Li, Ca, or an alloy or a compound thereof such as MgAg, MgIn, AlLi, or CaF₂, or calcium nitride may be used. In this manner, a light-emitting element 190 including the first electrode layer 185, the EL layer 188, and the second electrode layer 189 is formed (see FIG. 7B).

In the light-emitting device of this embodiment mode shown in FIGS. 7A and 7B, light from the light-emitting element 190 is emitted from the first electrode layer 185 side in a direction indicated by an arrow in FIG. 7B.

In this embodiment mode, an insulating layer may be provided as a passivation film (protective film) over the second electrode layer 189. It is effective to provide a passivation film so as to cover the second electrode layer 189 as described above. The passivation film may be formed using an insulating film containing silicon nitride, silicon oxide, silicon oxynitride, silicon nitride oxide, aluminum nitride, aluminum oxynitride, aluminum nitride oxide containing more nitrogen than oxygen, aluminum oxide, diamond-like carbon (DLC), or nitrogen-containing carbon, and a single layer or a stacked layer of the insulating films can be used. Alternatively, a siloxane resin may be used.

At this time, it is preferable to form the passivation film using a film by which favorable coverage is obtained, and it is effective to use a carbon film, particularly, a DLC film for the passivation film. A DLC film can be formed in the temperature range from room temperature to 100° C.; therefore, it can also be formed easily over the EL layer 188 with low heat resistance. A DLC film can be formed by a plasma CVD method (typically, an RF plasma CVD method, a microwave CVD method, an electron cyclotron resonance (ECR) CVD method, a heat filament CVD method, or the like), a combustion method, a sputtering method, an ion beam evaporation method, a laser evaporation method, or the like. As reaction gases for film formation, a hydrogen gas and a hydrocarbon-based gas (such as CH₄, C₂H₂, or C₆H₆) are used, and the gases are ionized by glow discharge, and the ions are accelerated to collide with a cathode to which negative self-bias is applied. Further, a CN film may be formed with the use of a C₂H₄ gas and a N₂ gas as reaction gases. A DLC film has high blocking effect against oxygen; therefore, oxidization of the EL layer 188 can be suppressed. Accordingly, a problem such as oxidation of the EL layer 188 during a sealing step which is performed later can be avoided.

The substrate 100, over which the light-emitting element 190 is formed as described above, and a sealing substrate 195 are firmly attached to each other with a sealing material 192, whereby the light-emitting element is sealed (see FIGS. 7A and 7B). As the sealing material 192, typically, a visible light curable resin, an ultraviolet light curable resin, or a thermosetting resin is preferably used. For example, a bisphenol-A liquid resin, a bisphenol-A solid resin, a bromine-containing epoxy resin, a bisphenol-F resin, a bisphenol-AD resin, a phenol resin, a cresol resin, a novolac resin, a cycloaliphatic epoxy resin, an Epi-Bis type epoxy resin, a glycidyl ester resin, a glycidyl amine-based resin, a heterocyclic epoxy resin, a modified epoxy resin, or the like can be used. It is to be noted that a region surrounded by the sealing material may be filled with a filler 193 or the region may be filled with nitrogen or the like by performing sealing in a nitrogen atmosphere. Since a bottom emission structure is employed in this embodiment mode, the filler 193 does not need to have a light-transmitting property. However, in a case where light is extracted through the filler 193, the filler needs to have a light-transmitting property. Typically, a visible light curable epoxy resin, an ultraviolet light curable epoxy resin, or a thermosetting epoxy resin may be used. Through the aforementioned steps, a light-emitting device having a display function using the light-emitting element of this embodiment mode is completed. Further, the filler may be dripped in a liquid state to fill a space in the light-emitting device. With the use of a hygroscopic substance like a drying agent as the filler, further moisture absorbing effect can be obtained, whereby the element can be prevented from deteriorating.

A drying agent is provided in an EL display panel to prevent deterioration of an element due to moisture. In this embodiment mode, the drying agent is provided in a depression that is formed in the sealing substrate so as to surround the pixel region, whereby a thin design is not hindered. Furthermore, because the drying agent is also formed in a region corresponding to a gate wiring layer to obtain a wide moisture absorbing area, moisture can be effectively absorbed. In addition, because the drying agent is formed over a gate wiring layer which does not emit light from itself, light extraction efficiency is not decreased, either.

The light-emitting element is sealed using a glass substrate in this embodiment mode. It is to be noted that sealing process is a process for protecting the light-emitting element from moisture, and is performed by one of the following methods: a method for mechanically sealing the light-emitting element by a cover material; a method for sealing the light-emitting element with a thermosetting resin or an ultraviolet light curable resin; and a method for sealing the light-emitting element by a thin film having a high barrier property such as a metal oxide film or a metal nitride film. As the cover material, glass, ceramics, plastics, or metal can be used, but when light is emitted from the cover material side, a light-transmitting material needs to be used. The cover material and the substrate over which the light-emitting element is formed are attached to each other with a sealing material such as a thermosetting resin or an ultraviolet light curable resin, and a sealed space is formed through curing of the resin by heat treatment or ultraviolet light irradiation treatment. It is also effective to provide a moisture absorbing material typified by barium oxide in this sealed space. This moisture absorbing material may be provided on and in contact with the sealing material, or over the partition wall or in the peripheral portion so as not to block light from the light-emitting element. Further, the space between the cover material and the substrate over which the light-emitting element is formed can be filled with a thermosetting resin or an ultraviolet light curable resin. In this case, it is effective to add a moisture absorbing material typified by barium oxide to the thermosetting resin or the ultraviolet light curable resin.

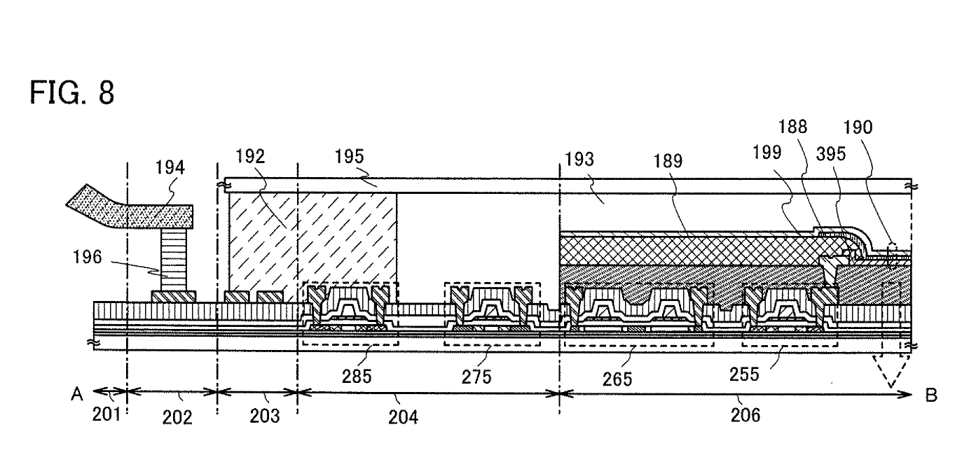

FIG. 8 shows an example in which, in the light-emitting device shown in FIGS. 7A and 7B manufactured in this embodiment mode, the source electrode layer or the drain electrode layer and the first electrode layer are not directly in contact with each other to be electrically connected, but connected to each other through a wiring layer. In a light-emitting device of FIG. 8, a source electrode layer or a drain electrode layer of a thin film transistor for driving a light-emitting element is electrically connected to a first electrode layer 395 through a wiring layer 199. In FIG. 8, the source electrode layer or the drain electrode layer is connected to the first electrode layer 395 so that part of the first electrode layer 395 is stacked over the wiring layer 199; however, the first electrode layer 395 may be formed first, and then, the wiring layer 199 may be formed on the first electrode layer 395.

In this embodiment mode, in the external terminal connection region 202, the terminal electrode layer 178 is connected to an FPC 194 through an anisotropic conductive layer 196 and electrically connected to an external portion. In addition, as shown in FIG. 7A that is a top view of the light-emitting device, the light-emitting device manufactured in this embodiment mode includes a peripheral driver circuit region 207 and a peripheral driver circuit region 208 each including a scan line driver circuit, in addition to the peripheral driver circuit region 204 and the peripheral driver circuit region 209 each including a signal line driver circuit.

The circuit as described above is used in this embodiment mode; however, the present invention is not limited thereto. An IC chip may be mounted as the peripheral driver circuit by the aforementioned COG method or TAB method. Further, one or more gate line driver circuits and source line driver circuits may be provided.

In the light-emitting device of the present invention, a driving method for image display is not particularly limited, and for example, a dot sequential driving method, a line sequential driving method, an area sequential driving method, or the like may be used. Typically, a line sequential driving method may be used, and a time division gray scale driving method or an area gray scale driving method may be appropriately used. Furthermore, a video signal input to the source lines of the light-emitting device may be an analog signal or a digital signal. The driver circuit and the like may be appropriately designed in accordance with the video signal.

Because the light-emitting element of this embodiment mode has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage, thereby achieving a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 6

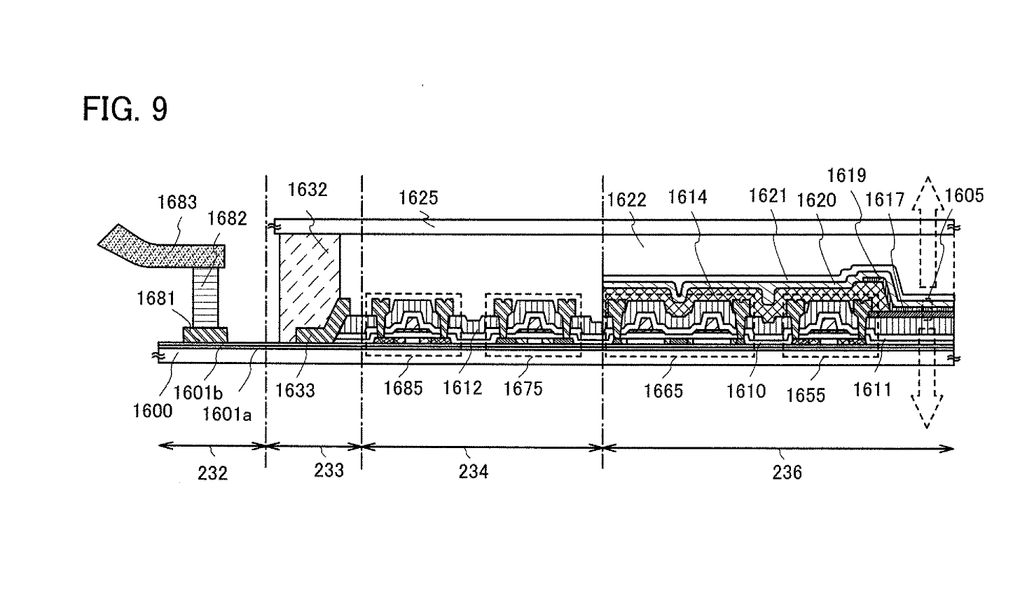

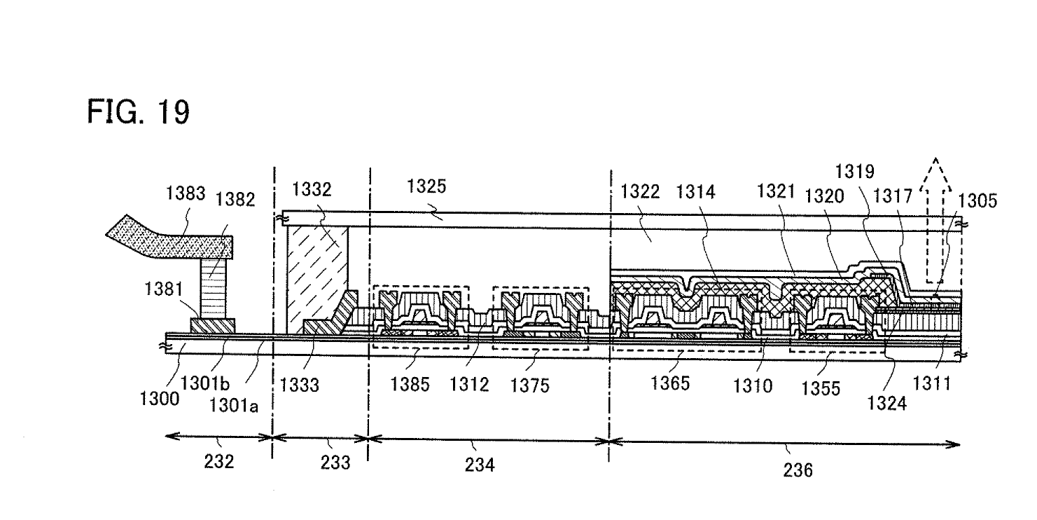

A light-emitting device having a light-emitting element can be formed by applying the present invention, and light is emitted from the light-emitting element in any type of bottom emission, top emission, and dual emission. In this embodiment mode, examples of a dual emission type and a top emission type will be described with reference to FIGS. 9 and 19. In this embodiment mode, examples in each of which the second interlayer insulating layer (the insulating film 181) is not formed in the light-emitting device which is manufactured according to Embodiment Mode 5. Therefore, repetitive description of the same portions or portions having similar functions is omitted.

A light-emitting device shown in FIG. 9 has an element substrate 1600, thin film transistors 1655, 1665, 1675, and 1685, a first electrode layer 1617, an EL layer 1619, a second electrode layer 1620, a protective film 1621, a filler 1622, a sealing material 1632, insulating films 1601a and 1601b, a gate insulating layer 1610, insulating films 1611 and 1612, an insulating layer 1614, a sealing substrate 1625, a wiring layer 1633, a terminal electrode layer 1681, an anisotropic conductive layer 1682, and an FPC 1683. The light-emitting device has an external terminal connection region 232, a sealing region 233, a peripheral driver circuit region 234, and a pixel region 236. The filler 1622 can be formed by a dropping method using a composition in a liquid state. The element substrate 1600 where the filler is formed by a dropping method and the sealing substrate 1625 are attached to each other, and the light-emitting device is sealed. The EL layer 1619 has a light-emitting layer which includes an inorganic light-emitting material containing a mixed-valence compound.

The EL layer 1619 provided between the electrode layers, which is manufactured using the present invention, has a light-emitting layer which includes an inorganic light-emitting material containing a mixed-valence compound. In addition, the EL layer 1619 may have an insulating layer as described in Embodiment Mode 1 and as shown in FIGS. 2A to 3C. A light-emitting element of this embodiment mode using the present invention can be specifically formed using the structure, material, and method that are described in Embodiment Mode 1.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows: Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound of this embodiment mode using the present invention can be formed using the material described in Embodiment Mode 1.

An inorganic light-emitting material that can be used in this embodiment mode includes a base material and an impurity element which serves as a light-emission center. By changing impurity elements to be included, various colors of light emission can be performed. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least on of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound. In an inorganic light-emitting material, an impurity element serving as a secondary activator may also be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When an impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state or may be generated in such a manner that a given valence state is excited and energy is transferred to another or the other valance state (or another or the other impurity element), and the valence state gaining the energy emits light.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly, chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

The light-emitting device of FIG. 9 is of a dual emission type, in which light is emitted from both the element substrate 1600 side and the sealing substrate 1625 side in directions indicated by arrows. Thus, a light-transmitting electrode layer is used as each of the first electrode layer 1617 and the second electrode layer 1620.

In this embodiment mode, the first electrode layer 1617 and the second electrode layer 1620, each of which is a light-transmitting electrode layer, may be specifically formed by using a transparent conductive film made of a light-transmitting conductive material, and indium oxide containing tungsten oxide, indium zinc oxide containing tungsten oxide, indium oxide containing titanium oxide, indium tin oxide containing titanium oxide, or the like can be used. It is needless to say that indium tin oxide (ITO), indium zinc oxide (IZO), indium tin oxide to which silicon oxide is added (ITSO), or the like can be used.

Even in the case of a non-light-transmitting material such as a metal film, when the thickness is made to be thin (preferably, approximately 5 nm to 30 nm) so as to be able to transmit light, light can be emitted through the first electrode layer 1617 and the second electrode layer 1620. As a metal thin film that can be used for the first electrode layer 1617 and the second electrode layer 1620, a conductive film made of titanium, tungsten, nickel, gold, platinum, silver, aluminum, magnesium, calcium, lithium, or an alloy thereof or the like can be used.

As described above, in the light-emitting device of FIG. 9, light emitted from a light-emitting element 1605 is transmitted through both the first electrode layer 1617 and the second electrode layer 1620, whereby light is emitted from both sides.

A light-emitting device shown in FIG. 19 has a top emission structure in which light is emitted in the direction of an arrow. The light-emitting device shown in FIG. 19 has an element substrate 1300, thin film transistors 1355, 1365, 1375, and 1385, a wiring layer 1324, a first electrode layer 1317, an EL layer 1319, a second electrode layer 1320, a protective film 1321, a filler 1322, a sealing material 1332, insulating films 1301a and 1301b, a gate insulating layer 1310, insulating films 1311 and 1312, an insulating layer 1314, a sealing substrate 1325, a wiring layer 1333, a terminal electrode layer 1381, an anisotropic conductive layer 1382, and an FPC 1383. The EL layer 1319 has a light-emitting layer which includes an inorganic light-emitting material containing a mixed-valence compound.

In each of the light-emitting devices of FIGS. 9 and 19, the insulating layer stacked over the terminal electrode layer is removed by etching. With such a structure where an insulating layer having a moisture permeable property is not provided in the periphery of the terminal electrode layer, reliability is further improved. The light-emitting device of FIG. 19 has an external terminal connection region 232, a sealing region 233, a peripheral driver circuit region 234, and a pixel region 236. In the light-emitting device of FIG. 19, the wiring layer 1324 which is a reflective metal layer is formed below the first electrode layer 1317 in the above-mentioned dual emission light-emitting device shown in FIG. 9. The first electrode layer 1317 which is a transparent conductive film is formed over the wiring layer 1324. It is acceptable as long as the wiring layer 1324 has reflectivity, so it may be formed using a conductive film made of titanium, tungsten, nickel, gold, platinum, silver, copper, tantalum, molybdenum, aluminum, magnesium, calcium, lithium, or an alloy thereof or the like. It is preferable to use a substance that has high reflectivity in a visible light region. In this embodiment mode, a titanium nitride film is used. The first electrode layer 1317 may also be formed using a conductive film, and in that case, the wiring layer 1324 having reflectivity may be omitted.

Each of the first electrode layer 1317 and the second electrode layer 1320 may be formed using a transparent conductive film made of a conductive material having a light-transmitting property, specifically, indium oxide containing tungsten oxide, indium zinc oxide containing tungsten oxide, indium oxide containing titanium oxide, indium tin oxide containing titanium oxide, or the like. It is needless to say that indium tin oxide (ITO), indium zinc oxide (IZO), indium tin oxide to which silicon oxide is added (ITSO), or the like can be used.

Even in the case of a non-light-transmitting material such as a metal film, when the thickness is made to be thin (preferably, approximately 5 nm to 30 nm) so as to be able to transmit light, light can be emitted through the second electrode layer 1620. As a metal thin film that can be used for the second electrode layer 1620, a conductive film made of titanium, tungsten, nickel, gold, platinum, silver, aluminum, magnesium, calcium, lithium, or an alloy thereof or the like can be used.

Each pixel of a light-emitting device which is formed by using a light-emitting element can be driven by a simple matrix method or an active matrix method. In addition, either digital driving or analog driving can be applied.

A color filter (colored layer) may be formed over a sealing substrate. The color filter (colored layer) can be formed by an evaporation method or a droplet discharging method. High-resolution display can be performed with the use of the color filter (colored layer). This is because a broad peak can be modified to be sharp in an emission spectrum of each of R, G, and B by the color filter (colored layer).

Full-color display can be performed by forming a material which emits light of a single color and using also a color filter or a color conversion layer. The color filter (colored layer) or the color conversion layer may be formed over, for example, a second substrate (a sealing substrate) and attached to a substrate.

Of course, display of a single color emission may also be performed. For example, an area-color type light-emitting device may be manufactured by using single color emission. The area-color type is suitable for a passive matrix display portion and can mainly display characters and symbols.

The first electrode layer 1617 and the second electrode layer 1620 can be formed by an evaporation method, a sputtering method, a CVD method, an EB evaporation method, a printing method, a dispenser method, a droplet discharging method, or the like.

Similarly, for the first electrode layer 1317 and the second electrode layer 1320, an evaporation method by resistance heating, an EB evaporation method, a sputtering method, a wet process, or the like can be used. This embodiment mode can be freely combined with any of Embodiment Modes 1 to 4.

Because the light-emitting element of this embodiment mode has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage, thereby achieving a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 7

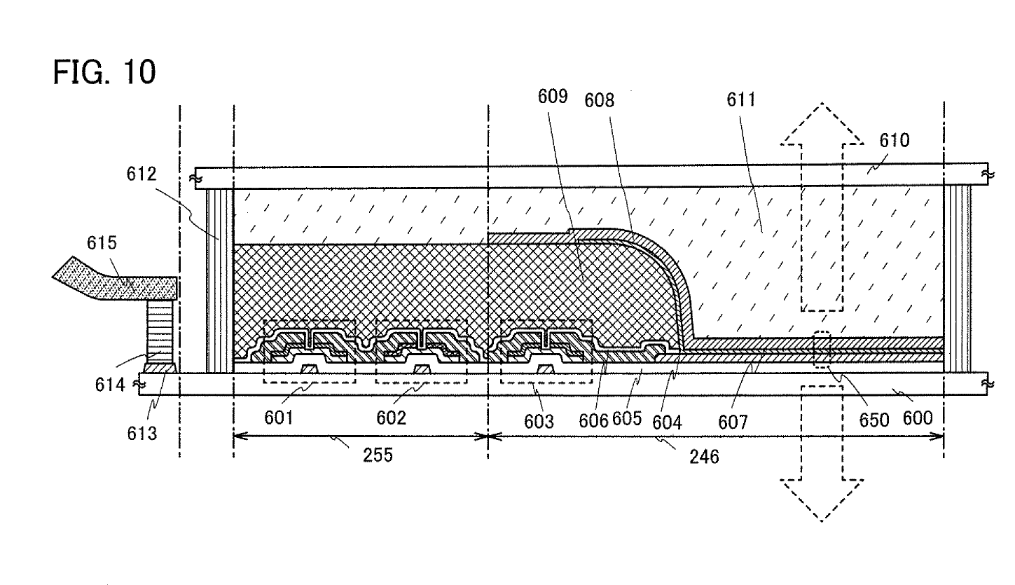

This embodiment mode of the present invention will be described with reference to FIG. 10. This embodiment mode shows an example in which, in the light-emitting device manufactured according to Embodiment Mode 4, a channel-etch inverted staggered thin film transistor is used as the thin film transistor and the first interlayer insulating layer and the second interlayer insulating layer are not formed. Therefore, repetitive description of the same portions or portions having similar functions is omitted.

A light-emitting device shown in FIG. 10 has, over a substrate 600, an inverted staggered thin film transistor 601 and an inverted staggered thin film transistor 602 in a peripheral driver circuit region 255; an inverted staggered thin film transistor 603, a gate insulating layer 605, an insulating film 606, an insulating layer 609, a light-emitting element 650 that is a stack of a first electrode layer 604, an EL layer 607, and a second electrode layer 608, a filler 611, and a sealing substrate 610 in a pixel region 246; and a sealing material 612, a terminal electrode layer 613, an anisotropic conductive layer 614, and an FPC 615 in a sealing region. The EL layer 607 has a light-emitting layer which includes an inorganic light-emitting material containing a mixed-valence compound.

The EL layer 607 provided between the electrode layers, which is manufactured using the present invention, is provided with a light-emitting layer which includes an inorganic light-emitting material containing a mixed-valence compound. In addition, the EL layer 607 may have an insulating layer as described in Embodiment Mode 1 and as shown in FIGS. 2A to 3C. The light-emitting element of this embodiment mode using the present invention can be specifically formed using the structure, material, and method that are described in Embodiment Mode 1.

When an element in a given compound has a plurality of valences, this element is in a state that is referred to as a mixed-valence state and this compound is referred to as a mixed-valence compound. An example of a mixed-valence state is a state in which an element M contained in a compound MX has +n and +m valences (n≠m), that is, a plurality of valences. An element may have three or more valences.

Specific examples of valences include a mixed state of +1 and +2 valences, a mixed state of +2 and +3 valences, and further a mixed state of +1, +2, and +3 valences. As valences that form a mixed-valence state, values are not necessarily consecutive and the case of a mixed state of +1 and +3 valences may be possible. Furthermore, in one compound, each of two or more elements may be in a mixed-valence state. For example, in the case of the above-mentioned compound MX, an element X has −a and −b valences (a≠b) and an element M has +n and +m valences (n≠m). The mixed-valence compound used in the present invention is an inorganic compound. Moreover, a compositional formula of the compound may be non-stoichiometric.

The compound can be in a mixed-valence state and the state (e.g., ratio of valences) thereof can be controlled depending on conditions for the formation or the synthesis. Examples of the conditions include a synthetic temperature, the kind of material and the quantity thereof to be mixed, and the like in synthesizing an objective compound. The compound can be in a mixed-valence state and the state thereof can also be controlled depending on a state in which a thin film is formed (film formation method such as vacuum evaporation or the like). Further, in some cases, an oxide or a sulfide can be in a mixed-valence state by a defect or by being doped with a certain element. The valence state can be classified into an ordered type and a disordered type according to the state. In a disordered type, an element having +n and +m valences (an atom having a +n valence and an atom having a +m valence) is randomly distributed in a crystal structure. On the other hand, in an ordered type, an atom having a +n valence and an atom having a +m valence of a single element is not randomly distributed but aligned in a certain site. For example, a compound is in a state in which only an atom having a +n valence is in one site and only an atom having a +m valence is in another site. It is considered that a disordered type is preferable for hopping conduction. Such mixed-valence compounds include a lot of materials having interesting properties, such as a superconductor and a sensor.

Hopping conduction (in some cases, referred to as Pool-Frenkel conduction) occurs in a mixed-valence compound because it has different valences. Such hopping conduction can thus improve charge (carrier) mobility. Therefore, when a mixed-valence compound is contained in a light-emitting layer of a light-emitting element, the light-emitting element can be driven at low voltage, thereby achieving a decrease in power consumption and an improvement in reliability.

In addition, valence affects emission color. Emission color varies with valence. Therefore, chromaticity of emission color can be adjusted by controlling the kind or ratio of valences. Furthermore, white light emission is also possible with a combination of complementary colors. Thus, the range of selection of emission color is expanded, and with the use of such a light-emitting element, a light-emitting device can be formed to emit various colors of light and have high image quality.

Such a valence state is, in short, a state with a plurality of oxidation states and is also referred to as valence fluctuation. An example of compound that can be in a mixed-valence state and can be used for the light-emitting layer of the present invention is a compound of a transition metal or a rare earth metal which can have a plurality of valences. Examples are as follows: Group 3 to 12 elements referred to as transition metal elements according to the periodic table; lanthanoids and actinoids referred to as rare earth metal elements; and Group 13 elements. In particular, a compound of any one of elements which belong to Groups 13 to 17 of the periodic table, such as a chalcogenide, like a sulfide or an oxide, or a halide, shows a mixed-valence state, and a complex compound of these compounds can similarly be in a mixed-valence state. A mixed-valence compound may contain single or plural metal elements that can each have a plurality of valences. The combination of materials can be freely set to obtain objective color or effect. It is acceptable as long as an inorganic light-emitting material containing a mixed-valence compound has a light-emitting function. Specifically, a light-emitting layer which includes an inorganic light-emitting material containing a mixed-valence compound of this embodiment mode using the present invention can be formed using the material described in Embodiment Mode 1.

An inorganic light-emitting material that can be used in this embodiment mode includes a base material and an impurity element which serves as a light-emission center. By changing impurity elements to be included, various colors of light emission can be performed. Plural kinds of impurity elements may be included. For example, in a case of donor-acceptor recombination type light emission, a light-emitting material that includes a first impurity element which forms a donor level and a second impurity element which forms an acceptor level as a light-emission center can be used. In the present invention, at least on of a base material and an impurity element serving as an activator (including a coactivator and a secondary activator), which are included in a light-emitting layer, contains a mixed-valence compound. It is needless to say that each of the base material and the impurity element, which are included in a light-emitting layer, may contain a mixed-valence compound. When an inorganic light-emitting material includes a base material, a first impurity element which forms a donor level, and a second impurity element which forms an acceptor level, at least one of them may be a mixed-valence compound, and it is needless to say that each of the base material, the first impurity element, and the second impurity element may be a mixed-valence compound. In an inorganic light-emitting material, an impurity element serving as a secondary activator may also be a mixed-valence compound.

When a base material is a mixed-valence compound, energy can be efficiently transferred from the base material with high charge mobility to an impurity element serving as an activator or a coactivator due to hopping conduction, whereby light emission can be obtained. Thus, a light-emitting element can be driven at low voltage.

When an impurity element serving as an activator or a coactivator is a mixed-valence compound, because the impurity element that contributes to light emission is in a mixed-valence state where the impurity element has a plurality of valences, light emission is not monochromatic and a wavelength spectrum of emission colors is broad or has two or more peaks. Accordingly, chromaticity of emission color of a light-emitting element can be adjusted. Furthermore, white light emission is also possible with a combination of complementary colors. Thus, the range of selection of emission color is expanded.

When the impurity element is in a mixed-valence state where the impurity element has a plurality of valences and when the impurity element is excited, energy transfer occurs between the plurality of valences, the impurity element is in a state with only one of the valences, and light emission only from the valance is obtained in some cases. This energy transfer occurs not only between different valences in one element but also between different elements. For example, when a plurality of impurity elements is added to a base material, one impurity element is in a mixed-valence state and excited; energy is transferred to another or the other impurity element; and the impurity element gaining the energy emits light.

In this manner, light emission may be generated from an excited valence state or may be generated in such a manner that a given valence state is excited and energy is transferred to another or the other valance state (or another or the other impurity element), and the valence state gaining the energy emits light.

Therefore, in a light-emitting layer which includes an inorganic light-emitting material containing a mixed-valence compound with a plurality of valences, energy can be efficiently transferred to an impurity element serving as a light-emission center due to high charge mobility; light having a plurality of wavelengths can be emitted; and a broad emission spectrum or a spectrum having two or more peaks can be obtained. Accordingly, chromaticity of emission color of a light-emitting element can be adjusted. Furthermore, white light emission is also possible with a combination of complementary colors. As a result, the range of selection of emission color is expanded. Therefore, low power consumption is achieved and various emission colors can be selected due to the adjustment of chromaticity of emission color and due to the emission of light of mixed color.

A gate electrode layer, a source electrode layer, and a drain electrode layer of each of the inverted staggered thin film transistors 601, 602, and 603 in this embodiment mode are formed by a droplet discharging method. A droplet discharging method is a method in which a composition including a conductive material in a liquid state is discharged and then solidified by drying and/or baking, whereby a conductive layer or an electrode layer is formed. When a composition containing an insulating material is discharged and then solidified by drying and/or baking, an insulating layer can also be formed. Because a component of a light-emitting device, such as a conductive layer or an insulating layer, can be selectively formed, steps are simplified and material loss can be prevented. Therefore, a light-emitting device can be manufactured at low cost with high productivity.

A droplet discharging unit used for a droplet discharging method is generally a unit to discharge liquid droplets, such as a nozzle equipped with a composition discharge outlet, a head having one or a plurality of nozzles. Each nozzle of the droplet discharging unit is set as follows: the diameter is 0.02 μm to 100 μm (preferably 30 μm or less) and the quantity of composition discharged from the nozzle is 0.001 pl to 100 pl (preferably 0.1 pl to 40 pl, and more preferably 10 pl or less). The discharge quantity is increased proportionately to the diameter of the nozzle. It is preferable that the distance between an object to be processed and the discharge outlet of the nozzle be as short as possible in order to drop droplets on a desired position; the distance is preferably set to be 0.1 mm to 3 mm (more preferably 1 mm or less).

In the case where a film (e.g., an insulating film or a conductive film) is formed by a droplet discharging method, the film is formed as follows: a composition containing a film material that is processed into particles is discharged and then fused or welded by baking to be solidified. A film formed by a sputtering method or the like tends to have a columnar structure, whereas the film thus formed by discharging and baking the composition containing a conductive material tends to have a polycrystalline structure having a large number of grain boundaries.

As the composition to be discharged from the discharge outlet, a conductive material dissolved or dispersed in a solvent is used. The conductive material corresponds to a fine particle or a dispersible nanoparticle of a metal such as Ag, Au, Cu, Ni, Pt, Pd, Ir, Rh, W, or Al; a metal sulfide of Cd, Zn or the like; an oxide of Fe, Ti, Si, Ge, Si, Zr, Ba, or the like; silver halide; or the like. The above-mentioned conductive materials may also be used in combination. Although a transparent conducive film transmits light in exposure of a back side because of its light-transmitting property, the transparent conductive film can be used as being a stacked body with a material that does not transmit light. As the transparent conductive film, indium tin oxide (ITO), indium tin oxide containing silicon oxide (ITSO), organic indium, organic tin, zinc oxide, titanium nitride, or the like can be used. Further, indium zinc oxide (IZO) containing zinc oxide (ZnO); zinc oxide (ZnO); ZnO doped with gallium (Ga); tin oxide (SnO₂); indium oxide containing tungsten oxide; indium zinc oxide containing tungsten oxide; indium oxide containing titanium oxide; indium tin oxide containing titanium oxide; or the like may also be used. As for the composition to be discharged from the discharge outlet, it is preferable to use any of the materials of gold, silver, and copper, dissolved or dispersed in a solvent, considering specific resistance and it is more preferable to use silver or copper having low resistance. When silver or copper is used, a barrier film is preferably provided together as a countermeasure against impurities. A silicon nitride film or a nickel boron (NiB) film can be used as the barrier film.

The composition to be discharged is a conductive material dissolved or dispersed in a solvent, which further contains a dispersant or a thermosetting resin. In particular, the thermosetting resin functions to prevent generation of cracks or uneven baking during baking. Thus, a resultant conductive layer may contain an organic material. The organic material to be contained is different depending on heating temperature, atmosphere, and time period. This organic material is an organic resin that functions as a thermosetting resin, a solvent, a dispersant, and a coating of a metal particle, or the like; typical examples thereof include polyimide, acrylic, a novolac resin, a melamine resin, a phenol resin, an epoxy resin, a silicone resin, a furan resin, a diallylphthalate resin, and other organic resins.

In addition, a particle with a plurality of layers, in which a conductive material is coated with another conductive material, may also be used. For example, a particle with a three-layer structure, in which copper is coated with nickel boron (NiB) and the nickel boron is further coated with silver, may be used. For the solvent, esters such as butyl acetate or ethyl acetate, alcohols such as isopropyl alcohol or ethyl alcohol, an organic solvent such as methyl ethyl ketone or acetone, or water is used. The viscosity of the composition is preferably 20 mPa·s (cp) or less, which prevents the composition from drying and allows the composition to be discharged smoothly from the discharge outlet. The surface tension of the composition is preferably 40 mN/m or less. Note that the viscosity and the like of the composition may be appropriately adjusted in accordance with a solvent to be used or an intended purpose. For example, the viscosity of a composition in which ITO, organic indium, or organic tin is dissolved or dispersed in a solvent may be set to be 5 mPa·s to 20 mPa·s, the viscosity of a composition in which silver is dissolved or dispersed in a solvent may be set to be 5 mPa·s to 20 mPa·s, and the viscosity of a composition in which gold is dissolved or dispersed in a solvent may be set to be 5 mPa·s to 20 mPa·s.

Further, a conductive layer may also be formed as a stack of plural layers of conductive materials. In addition, the conductive layer may be formed first by a droplet discharging method using silver as a conductive material and may be then plated with copper or the like. The plating may be performed by electroplating or chemical (electroless) plating. The plating may be performed by immersing a substrate surface in a container filed with a solution containing a plating material; alternatively, the solution containing a plating material may be applied to the substrate placed obliquely (or vertically) so as that the solution containing a plating material flows over the substrate surface. When the plating is performed by application of a solution to the substrate placed obliquely, there is an advantage of miniaturizing a process apparatus.

The diameter of the particle of the conductive material is preferably as small as possible for preventing nozzles from being clogged and for forming a minute pattern, although it depends on the diameter of each nozzle, the shape of a desired pattern, and the like. Preferably, the diameter of the particle of the conductive material is 0.1 μm or less. The composition is formed by a known method such as an electrolyzing method, an atomizing method, or a wet reduction method, and the particle size thereof is generally about 0.01 μm to 10 μm. When a gas evaporation method is employed, the size of nanoparticles protected by a dispersant is as minute as about 7 nm. When a surface of each nanoparticle is covered with a coating, the nanoparticles do not aggregate in the solvent and are stably dispersed in the solvent at room temperature, and exhibit similar behavior to liquid. Accordingly, it is preferable to use a coating.

In addition, the step of discharging the composition may be performed under reduced pressure. When the step is performed under reduced pressure, an oxide film or the like is not formed on the surface of the conductive material, which is preferable. After the composition is discharged, one or both of drying and baking are performed. Both the drying step and baking step are heat treatment; however, for example, drying is performed at 100° C. for 3 minutes, baking is performed at 200° C. to 350° C. for 15 minutes to 60 minutes, and they are different in purpose, temperature, and time period. The steps of drying and baking are performed under normal pressure or under reduced pressure, by laser beam irradiation, rapid thermal annealing, heating using a heating furnace, or the like. Note that the timing of each heat treatment is not particularly limited. The substrate may be heated in advance to favorably perform the steps of drying and baking, and the temperature at that time is, although it depends on the material of the substrate or the like, generally 100° C. to 800° C. (preferably, 200° C. to 350° C.). Through these steps, nanoparticles are made in contact with each other and fusion and welding are accelerated since a peripheral resin is hardened and shrunk, while the solvent in the composition is volatilized or the dispersant is chemically removed.

A continuous-wave or pulsed gas laser or solid-state laser may be used for the laser beam irradiation. An excimer laser, a YAG laser, or the like can be used as the former gas laser. A laser using a crystal of YAG, YVO₄, GdVO₄, or the like which is doped with Cr, Nd, or the like can be used as the latter solid-state laser. It is preferable to use a continuous-wave laser in consideration of the absorptance of a laser beam. Alternatively, a laser irradiation method in which pulsed and continuous-wave lasers are combined may be used. It is preferable that the heat treatment by laser beam irradiation be rapidly performed within several microseconds to several tens of seconds so as not to damage the substrate 600, depending on the heat resistance of the substrate 600. Rapid thermal annealing (RTA) is carried out by raising the temperature rapidly and heating the substrate instantaneously for several microseconds to several minutes with the use of an infrared lamp or a halogen lamp that emits ultraviolet to infrared light in an inert gas atmosphere. Because this treatment is performed instantaneously, only an outermost thin film can be heated and the lower layer of the film is not adversely affected. In other words, even a substrate having low heat resistance such as a plastic substrate is not adversely affected.

After the conductive layer, the insulating layer, or the like is formed by discharging a composition by a droplet discharging method, a surface thereof may be planarized by pressing with pressure to enhance planarity. The pressing may be performed as follows: unevenness is reduced by rolling a roller-shaped object on the surface, the surface is pressed with a flat plate-shaped object, or the like. A heating step may also be performed at the time of the pressing. Alternatively, the unevenness of the surface may be removed with an air knife after the surface is softened or melted with a solvent or the like. A CMP method may also be used for polishing the surface. This step can be employed in planarizing the surface when unevenness is generated by a droplet discharging method.

In this embodiment mode, an amorphous semiconductor is used for a semiconductor layer and a semiconductor layer having one conductive type may be formed as needed. In this embodiment mode, an amorphous n-type semiconductor layer as a semiconductor layer having one conductive type is stacked over the semiconductor layer. Further, an NMOS structure with an n-channel TFT in which an n-type semiconductor layer is formed, a PMOS structure with a p-channel TFT in which a p-type semiconductor layer is formed, and a CMOS structure with an n-channel TFT and a p-channel TFT can be formed. In this embodiment mode, the inverted staggered thin film transistors 601 and 603 are n-channel TFTs, and the inverted staggered thin film transistor 602 is a p-channel TFT, whereby the inverted staggered thin film transistors 601 and 602 form a CMOS structure in the peripheral driver circuit region 255.

Moreover, in order to impart conductivity, an element imparting conductivity is added by doping to form an impurity region in the semiconductor layer; therefore, an n-channel TFT or a p-channel TFT can be formed. Instead of forming an n-type semiconductor layer, conductivity may be imparted to the semiconductor layer by plasma treatment with a PH₃ gas.

Further, the semiconductor layer can be formed using an organic semiconductor material by a printing method, a spray method, a spin coating method, a droplet discharging method, a dispenser method, or the like. In this case, the aforementioned etching step is not required; therefore, the number of steps can be reduced. As an organic semiconductor, a low molecular material such as pentacene, a high molecular material, or the like can be used, and a material such as an organic pigment or a conductive high molecular material can be used as well. As the organic semiconductor material used in the present invention, a n-conjugated high molecular material of which a skeleton is composed of conjugated double bonds is preferable. Typically, a soluble high molecular material such as polythiophene, polyfluorene, poly(3-alkylthiophene), or a polythiophene derivative can be used.

A light-emitting element that can be applied to the present invention can employ any of the structures described in the above embodiment modes.

This embodiment mode can be combined with each of Embodiment Modes 1 to 4.

Because the light-emitting element of this embodiment mode has an EL layer provided with a light-emitting layer, which includes an inorganic light-emitting material containing a mixed-valence compound, between a pair of electrode layers, the light-emitting layer has higher electron transportability. Therefore, the light-emitting element can be driven at low voltage, thereby achieving a reduction in power consumption and an improvement in reliability.

In addition, emission color varies with valence. Therefore, chromaticity of emission color can be adjusted by controlling the kind or ratio of valences. Furthermore, white light emission is also possible with a combination of complementary colors. Thus, the range of selection of emission color of a light-emitting element is expanded. With the use of such a light-emitting element, a light-emitting device can be formed to emit various colors of light and have high image quality.

Therefore, the light-emitting device having the light-emitting element of this embodiment mode using the present invention consumes less power, has high reliability and high image quality, and emits various colors of light.

### Embodiment Mode 8

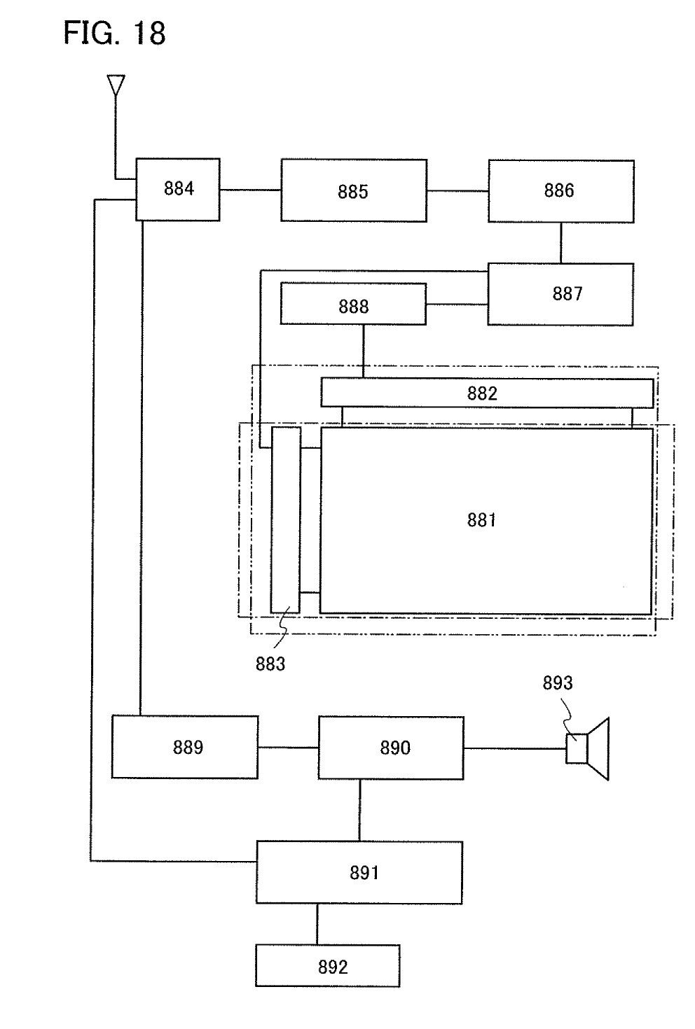

The light-emitting device formed according to the present invention can also function as a light-emitting display device that performs display. With the light-emitting display device of the present invention, a television device can be completed. FIG. 18 is a block diagram showing main components of a television device (an EL television device in this embodiment mode). As a display panel, there are cases in which only a pixel portion 881 is formed in the display panel as shown in FIG. 16A and a scan line side driver circuit 883 and a signal line side driver circuit 882 are mounted to the display panel by a TAB method as shown in FIG. 17B; cases in which only a pixel portion 881 is formed in the display panel as shown in FIG. 16A and a scan line side driver circuit 883 and a signal line side driver circuit 882 are mounted to the display panel by a COG method as shown in FIG. 17A; cases in which TFTs are formed using a SAS, a pixel portion 881 and a scan line side driver circuit 883 are formed over the same substrate as shown in FIG. 16B, and a signal line side driver circuit 882 is formed separately and mounted to the display panel as a driver IC; cases in which a pixel portion 881, a scan line side driver circuit 883, and a signal line side driver circuit 882 are formed over the same substrate as shown in FIG. 16C; and the like, but any kind of mode may be used.

As other external circuit components, there are, on the video signal input side, a video signal amplifier circuit 885 used to amplify video signals out of signals received by a tuner 884; a video signal processing circuit 886 used to convert signals output from the video signal amplifier circuit 885 into color signals corresponding to each color of red, green, and blue; a control circuit 887 used to convert those video signals into input specifications for a driver IC; and the like. The control circuit 887 outputs signals to both the scanning line side and the signal line side. When digital drive is used, the structure may be one in which a signal divider circuit 888 is provided on the signal line side and an input digital signal is divided into m signals and supplied.

Of signals that are received by the tuner 884, audio signals are transmitted to an audio signal amplifier circuit 889, and the output thereof is supplied to a speaker 893 through an audio signal processing circuit 890. A controller circuit 891 receives information for control of receiving station (receiving frequency) and volume from an input portion 892, and signals are sent out to the tuner 884 and the audio signal processing circuit 890.

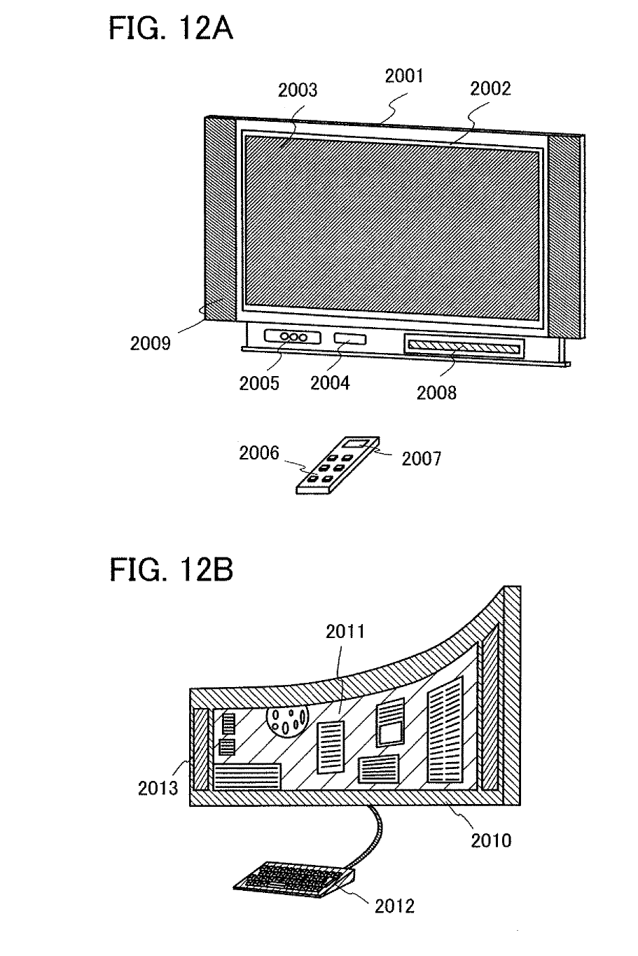

A television device can be completed by incorporation of a display module into a chassis, as shown in each of FIGS. 12A and 12B. An object including from a display panel to an FPC as shown in FIGS. 7A and 7B is generally referred to as an EL display module. An EL television can be completed with use of such an EL display module as shown in FIGS. 7A and 7B. A main screen 2003 is formed of the display module, and speaker portions 2009, operation switches, and the like are provided as accessory equipment. As thus described, a television device can be completed in accordance with the present invention.

In addition, reflected light of light entering from an external portion may be blocked with the use of a retardation plate or a polarizing plate. In a top emission light-emitting device, an insulating layer serving as a partition wall may be colored and used as a black matrix. This partition wall can be formed by a droplet discharging method or the like. Carbon black or the like may be mixed into a black resin of a pigment material or a resin material such as polyimide, and a stacked layer thereof may also be used. By a droplet discharging method, different materials may be discharged to the same region plural times to form the partition wall. A quarter-wave plate or a half-wave plate may be used as the retardation plate and may be designed to be able to control light. As the structure, a TFT element substrate, a light-emitting element, a sealing substrate (sealing material), a retardation plate (quarter-wave plate or half-wave plate), and a polarizing plate are sequentially provided, and light emitted from the light-emitting element is transmitted therethrough and emitted to an external portion from the polarizing plate side. The retardation film, the polarizing plate, or the like may be stacked. The retardation plate or polarizing plate may be provided on a side to which light is emitted or may be provided on both sides in the case of a dual emission light-emitting device in which light is emitted from the both surfaces. In addition, an anti-reflective film may be provided on the outer side of the polarizing plate. Accordingly, more high-definition and precise images can be displayed.

As shown in FIG. 12A, a display panel 2002 using a light-emitting element is incorporated into a chassis 2001. With the use of a receiver 2005, in addition to reception of general TV broadcast, information communication can also be carried out in one way (from a transmitter to a receiver) or in two ways (between a transmitter and a receiver or between receivers) by connection to a communication network by a fixed line or wirelessly through a modem 2004. The operation of the television device can be carried out by switches incorporated in the chassis or by a remote control operator 2006, which is separated from the main body. A display portion 2007 that displays information to be output may also be provided in this remote control device.

In addition, in the television device, a structure for displaying a channel, sound volume, or the like may be additionally provided by formation of a sub-screen 2008 with a second display panel in addition to the main screen 2003. In this structure, the main screen 2003 may be formed using an EL display panel which is superior in viewing angle, and the sub-screen 2008 may be formed using a liquid crystal display panel which is capable of display with less power consumption. In order to prioritize less power consumption, a structure in which the main screen 2003 is formed using a liquid crystal display panel, the sub-screen 2008 is formed using an EL display panel, and the sub-screen is able to turned on or off may also be employed. In accordance with the present invention, a highly reliable light-emitting device can be manufactured even by using such a large substrate with many TFTs and electronic parts.

FIG. 12B shows a television device having a large display portion. e.g. 20-inch to 80-inch display portion, which has a chassis 2010, a keyboard portion 2012 which is an operation portion, a display portion 2011, a speaker portion 2013, and the like. The present invention is applied to manufacture of the display portion 2011. For the display portion of FIG. 12B, a flexible material is used; therefore, a television device with a curved display portion is obtained. In this manner, the shape of the display portion can be freely designed; therefore, a television device in a desired shape can be manufactured.

According to the present invention, a light-emitting device with less power consumption, high reliability, and high image quality with various emission colors can be formed. Accordingly, a television device with less power consumption, high reliability, and high image quality can be manufactured.

Of course, the present invention is not limited to the television device and is also applicable to various applications such as display media having a large area, for example, a monitor of a personal computer, an information display board at a train station, an airport, or the like, or an advertisement display board on the street.

This embodiment mode can be combined with each of Embodiment Modes 1 to 6.

### Embodiment Mode 9

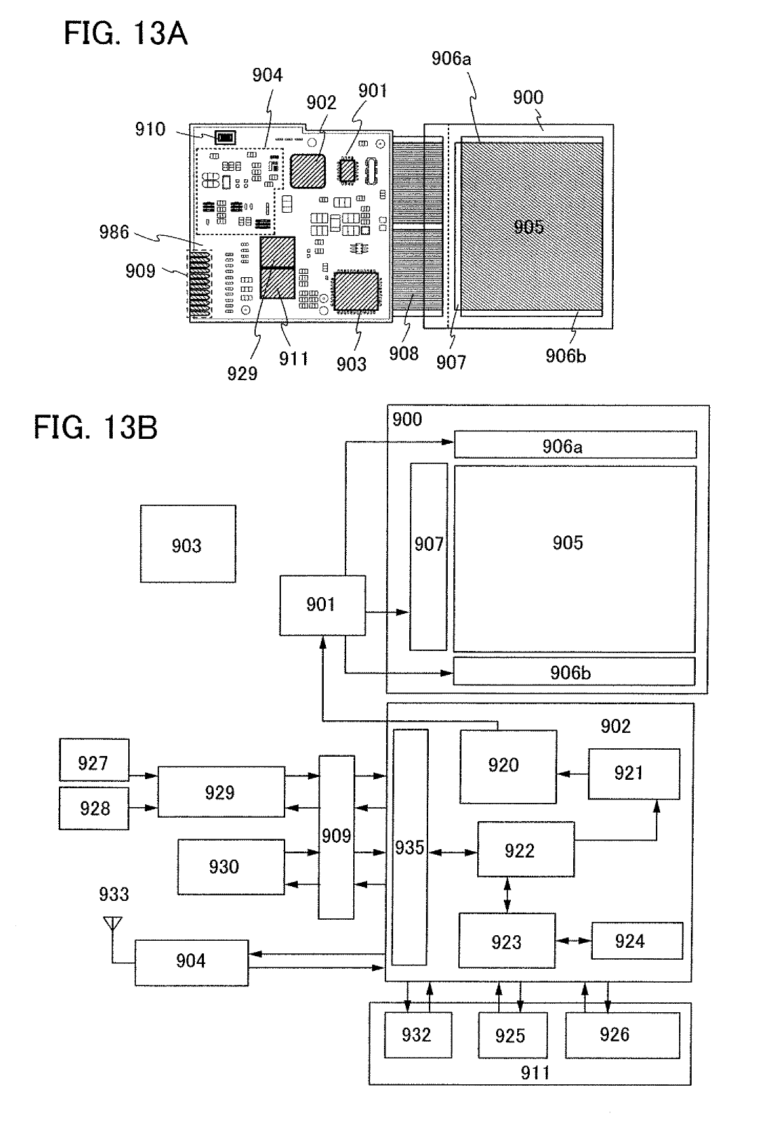

This embodiment mode will be described with reference to FIGS. 13A and 13B. In this embodiment mode, an example of a module that uses a panel having any of the light-emitting devices manufactured according to Embodiment Modes 3 to 7 will be described.

In a module of an information terminal shown in FIG. 13A, a printed wiring board 986 is mounted with a controller 901, a central processing unit (CPU) 902, a memory 911, a power supply circuit 903, an audio processing circuit 929, a transmission and reception circuit 904, and other elements such as a resistor, a buffer, and a capacitor. A panel 900 is connected to the printed wiring board 986 through a flexible printed circuit (FPC) 908.

The panel 900 has a pixel portion 905 in which each pixel has a light-emitting element, a first scan line driver circuit 906a and a second scan line driver circuit 906b which are used to select a pixel in the pixel portion 905, and a signal line driver circuit 907 which is used to supply a video signal to the selected pixel.

Various control signals are input and output through an interface (I/F) portion 909 that is provided on the printed wiring board 986. In addition, an antenna port 910 which is used to transmit and receive signals to and from an antenna is provided on the printed wiring board 986.

Note that, although the printed wiring board 986 in this embodiment mode is connected to the panel 900 through the FPC 908, there is no limitation on structures. The controller 901, the audio processing circuit 929, the memory 911, the CPU 902, or the power supply circuit 903 may be directly mounted on the panel 900 by a chip-on-glass (COG) method. In addition, the printed wiring board 986 is provided with various kinds of elements such as a capacitor and a buffer to prevent a noise in a power supply voltage or in a signal and a rounded rise of a signal.

FIG. 13B is a block diagram of the module shown in FIG. 13A. This module 999 has a VRAM 932, a DRAM 925, a flash memory 926, and the like as the memory 911. The VRAM 932 stores image data to be displayed on the panel; the DRAM 925 stores image data or audio data; and the flash memory 926 stores various programs.

The power supply circuit 903 generates a power supply voltage to be applied to the panel 900, the controller 901, the CPU 902, the audio processing circuit 929, the memory 911, and a transmission and reception circuit 904. Depending on the specifications of the panel, a current source may be provided in the power source circuit 903.

The CPU 902 has a control signal generating circuit 920, a decoder 921, a register 922, an arithmetic circuit 923, a RAM 924, an interface 935 for the CPU, and the like. Various signals input to the CPU 902 through the interface 935 are held in the register 922 once and then input to the arithmetic circuit 923, the decoder 921, and the like. The arithmetic circuit 923 performs an arithmetic operation based on the input signal and designates the destination of various instructions. Meanwhile, a signal input to the decoder 921 is decoded and input to the control signal generating circuit 920. The control signal generating circuit 920 generates a signal, which contains various instructions based on the input signal, and then transmits the signal to the destination designated by the arithmetic circuit 923, specifically, to the memory 911, the transmission and reception circuit 904, the audio processing circuit 929, the controller 901, or the like.

The memory 911, the transmission and reception circuit 904, the audio processing circuit 929, and the controller 901 operate in accordance with respective received instructions. The operation will be described below.

The signal input from an input unit 930 is transmitted to the CPU 902, which is mounted on the printed wiring board 986, through the interface 909. The control signal generating circuit 920 converts the image data stored in the VRAM 932 into a predetermined format in accordance with the signal transmitted from the input unit 930 such as a pointing device or a keyboard and then transmits it to the controller 901.

The controller 901 processes a signal containing image data transmitted from the CPU 902 in accordance with the specifications of the panel and supplies it to the panel 900. Furthermore, the controller 901 generates an Hsync signal, a Vsync signal, a clock signal CLK, an AC voltage (AC Cont), and a switching signal UR based on the power supply voltage input from the power supply circuit 903 and the various signals input from the CPU 902, and supplies the signals to the panel 900.

In the transmission and reception circuit 904, a signal to be transmitted to and received from an antenna 933 as an electric wave is processed. Specifically, the transmission and reception circuit 904 includes a high frequency circuit such as an isolator, a band-pass filter, a voltage-controlled oscillator (VCO), or a low-pass filter (LPF). Of the signals transmitted and received by the transmission and reception circuit 904, a signal containing audio information is transmitted to the audio processing circuit 929 in accordance with the instruction from the CPU 902.

The signal containing audio information transmitted in accordance with the instruction from the CPU 902 is demodulated into audio signals in the audio processing circuit 929 and transmitted to a speaker 928. The audio signal transmitted from a microphone 927 is modulated in the audio processing circuit 929 and transmitted to the transmission and reception circuit 904 in accordance with the instruction from the CPU 902.

The controller 901, the CPU 902, the power supply circuit 903, the audio processing circuit 929, and the memory 911 can be mounted as a package of this embodiment mode. This embodiment mode can be applied to any circuits except for high frequency circuits such as an isolator, a band-pass filter, a voltage-controlled oscillator (VCO), a low-pass filter (LPF), a coupler, and a balun.

### Embodiment Mode 10

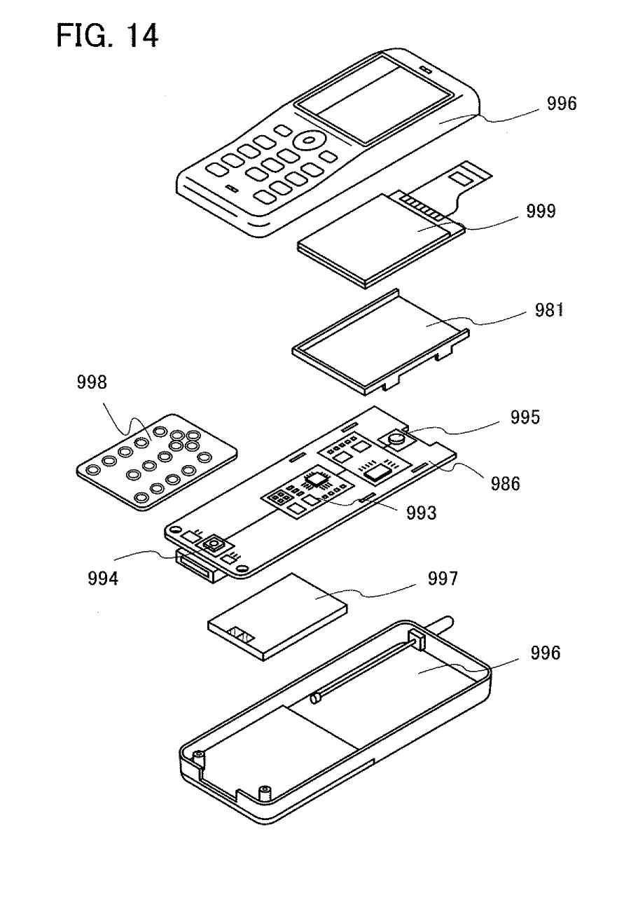

This embodiment mode will be described with reference to FIG. 14. FIG. 14 shows a mode of a portable compact wireless phone (cellular phone) having a module manufactured according to this embodiment mode. A panel 900 is designed to be detachably incorporated in a housing 981 so as to be easily combined with a module 999. The shape and dimension of the housing 981 can be changed appropriately in accordance with an electronic device in which the housing 981 is to be incorporated.

The housing 981 to which the panel 900 is fixed is fit in a printed wiring board 986 and set up as a module. On the printed wiring board 986, a plurality of packaged semiconductor devices is mounted. The plurality of semiconductor devices mounted on the printed wiring board 986 functions as any of a controller, a central processing unit (CPU), a memory, a power supply circuit, a resistor, a buffer, a capacitor, and the like. Furthermore, an audio processing circuit including a microphone 994 and a speaker 995, and a signal processing circuit 993 such as a transmission and reception circuit are provided. The panel 900 is connected to the printed wiring board 986 through the FPC 908.

The module 999, the housing 981, the printed wiring board 986, an input unit 998, and a battery 997 are stored in a housing 996. A pixel portion of the panel 900 is located so that it can be seen through a window formed in the chassis 996.

The housing 996 shown in FIG. 14 shows an exterior shape of a phone as an example. However, the electronic device of this embodiment mode can be changed to be various modes in accordance with the functions or the intended use. An example of the modes will be described in the following embodiment mode.

### Embodiment Mode 11

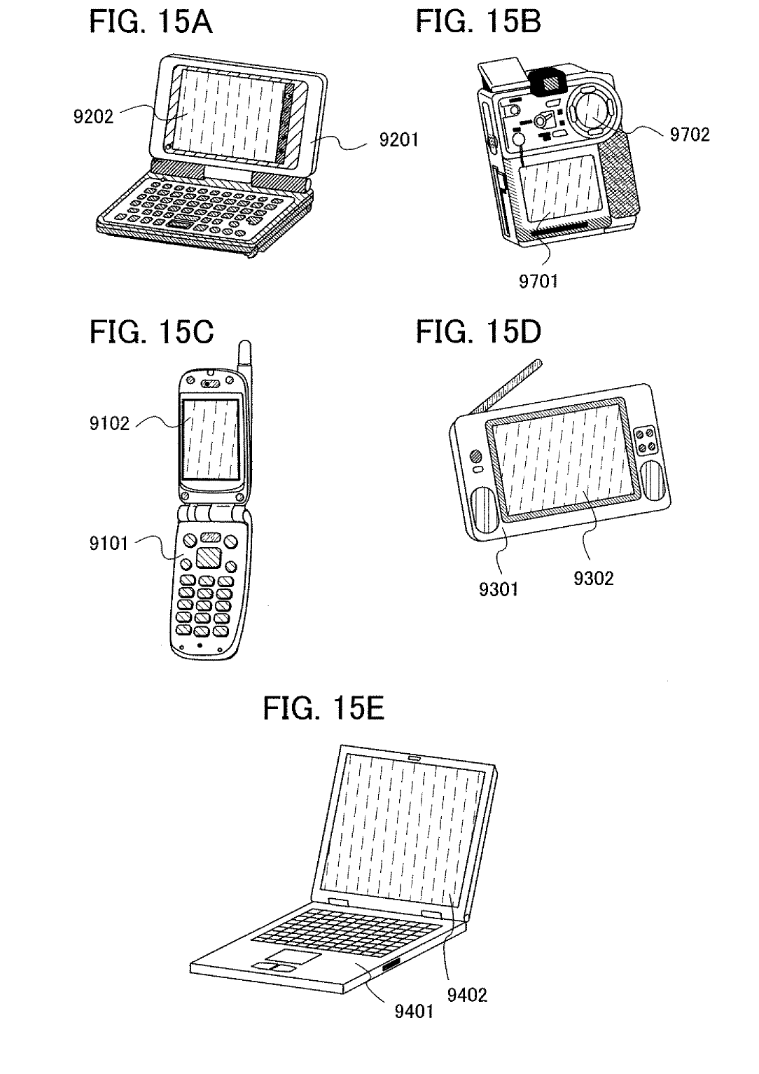

Examples of electronic devices according to the present invention are as follows: a television device (also simply referred to as a television or a television receiver), a camera such as a digital camera or digital still camera, a cellular phone device (also simply referred to as a cellular phone or a cell-phone), a portable information terminal such as a PDA, a portable game machine, a computer monitor, a computer, an audio reproducing device such as a car audio component, an image reproducing device such as a home-use game machine, and the like. The specific examples will be described with reference to FIGS. 15A to 15E.

A portable information terminal shown in FIG. 15A has a main body 9201, a display portion 9202, and the like. To the display portion 9202, the light-emitting device of the present invention can be applied. Accordingly, a portable information terminal with less power consumption, high reliability, and high image quality can be provided.

A digital video camera shown in FIG. 15B has a display portion 9701, a display portion 9702, and the like. To the display portion 9701, the light-emitting device of the present invention can be applied. Accordingly, a digital video camera with less power consumption, high reliability, and high image quality can be provided.

A cellular phone shown in FIG. 15C has a main body 9101, a display portion 9102, and the like. To the display portion 9102, the light-emitting device of the present invention can be applied. Accordingly, a cellular phone with less power consumption, high reliability, and high image quality can be provided.

A portable television device shown in FIG. 15D has a main body 9301, a display portion 9302, and the like. To the display portion 9302, the light-emitting device of the present invention can be applied. Accordingly, a portable television device with less power consumption, high reliability, and high image quality can be provided. As a television device, the light-emitting device of the present invention can be applied to a wide range of television devices such as a small-sized television incorporated in a portable terminal such as a cellular phone, a medium-sized television device that is portable, and a large-sized television device (for example, a 40-inch or larger television device).

A portable computer shown in FIG. 15E has a main body 9401, a display portion 9402, and the like. To the display portion 9402, the light-emitting device of the present invention can be applied. Accordingly, a portable computer with less power consumption, high reliability, and high image quality can be provided.

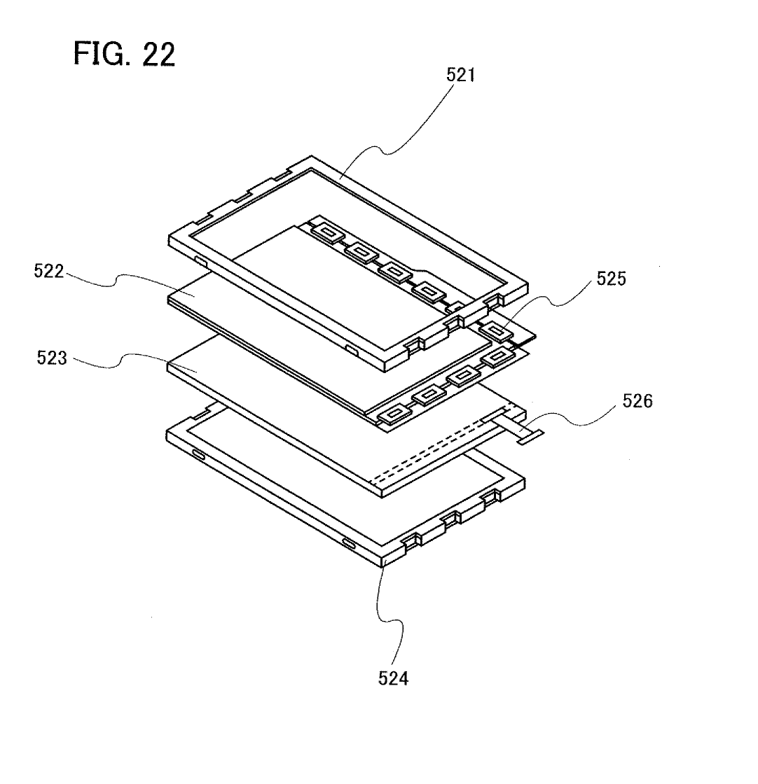

The light-emitting element and the light-emitting device of the present invention can also be used as a lighting system. One mode of using the light-emitting element of the present invention as a lighting system will be described with reference to FIGS. 22 to 24.

FIG. 22 shows an example of a liquid crystal display device using the light-emitting device of the present invention as a backlight. The liquid crystal display device shown in FIG. 22 has a chassis 521, a liquid crystal layer 522, a backlight 523, and a chassis 524, and the liquid crystal layer 522 is connected to a driver IC 525. The light-emitting device of the present invention is used for the backlight 523, which is supplied with an electric current through a terminal 526.

By using the light-emitting device of the present invention as a backlight of a liquid crystal display device, a backlight with long life time, which is unique to inorganic EL, can be obtained. The light-emitting device of the invention is a plane-emission lighting system and can be increased in size. Therefore, it becomes possible to increase the size of a backlight and also a liquid crystal display device. Furthermore, since the light-emitting device is thin, it becomes possible to reduce the thickness of a display device.

In addition, the light-emitting device of the present invention can be used as a headlight of a car, bicycle, ship, or the like.

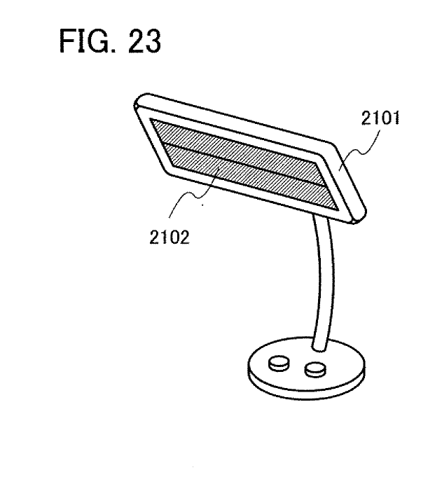

FIG. 23 shows an example in which the light-emitting device to which the present invention is applied is used as a desk lamp that is one of lighting systems. The desk lamp shown in FIG. 23 has a chassis 2101 and a light source 2102, and the light-emitting device of the present invention is used as the light source 2102. Since the light-emitting device of the present invention is thin and consumes less power, it can be used for a lighting system that is thinner and consumes less power.

FIG. 24 shows an example in which the light-emitting device to which the present invention is applied is used as an interior lighting system 3001. Since the light-emitting device of the present invention can be increased in size, it can be used as a large-area lighting system. In addition, since the light-emitting device of the present invention is thin and consumes less power, it can be used for a lighting system that is thinner and consumes less power A television device of the present invention as described with FIGS. 12A and 12B can be placed in a room in which the light-emitting device to which the present invention is applied is used as the indoor lighting system 3001 in such a manner, where public broadcasting and movies can be enjoyed. In such a case, powerful images can be appreciated in a bright room without concerns about electricity costs, because each of the lighting system and the television device consumes low power.

The lighting system is not limited to those illustrated in FIGS. 22 to 24 and is applicable as various types of lighting systems such as lighting for houses or public facilities. In such a case, since a light-emitting medium of the lighting system in accordance with the present invention has a thin film shape, the degree of freedom for design is high. Therefore, various elaborately-designed products can be provided to the market.

As described above, due to the light-emitting device of the present invention, an electronic device with less power consumption, high reliability, and high image quality can be provided. This embodiment mode can be freely combined with any of the above-described embodiment modes.

This application is based on Japanese Patent Application serial No. 2007-056546 filed with Japan Patent Office on Mar. 7, 2007, the entire contents of which are hereby incorporated by reference.

1. A light-emitting element comprising a light-emitting layer, which includes an inorganic light-emitting material containing a base material and an impurity element, between a first electrode layer and a second electrode layer,
wherein at least one of the base material and the impurity element is a mixed-valence compound.

2. The light-emitting element according to claim 1, wherein the light-emitting layer is a thin film of the inorganic light-emitting material.

3. The light-emitting element according to claim 1, wherein the inorganic-light-emitting material included in the light-emitting layer is dispersed in a binder.

4. The light-emitting element according to claim 1, further comprising an insulating layer on at least one of the first electrode layer side and the second electrode layer side of the light-emitting layer.

5. The light-emitting element according to claim 1, wherein the mixed-valence compound includes a transition metal element or a rare earth metal element.

6. The light-emitting element according to claim 1, wherein an element of the mixed-valence compound has a plurality of valences.

7. The light-emitting element according to claim 1, wherein a plurality of elements of the mixed-valence compound each has a plurality of valences.

8. A light-emitting device comprising the light-emitting element according to claim 1.
